(19) United States
(12) Patent Application Publication
(10) Pub. No.: US 2014/0240645 A1
(43) Pub. Date: Aug. 28, 2014

(54) PHOTOSENSITIVE RESIN COMPOSITION, DISPLAY DEVICE USING THE SAME AND METHOD OF MANUFACTURING THE DISPLAY DEVICE

(71) Applicant: Samsung Display Co., Ltd., Yongin-City (KR)

(72) Inventors: SeungBo SHIM, Asan-si (KR); Yang-Ho JUNG, Seoul (KR); Jinho JU, Seoul (KR); Hyang-Shik KONG, Seongnam-si (KR); Junhong PARK, Yongin-si (KR); Nam-Yi KIM, Anyang-si (KR); Byung uk KIM, Hwaseong-si (KR); Jinsun KIM, Hwaseong-si (KR); TAI HOON YEO, Hwaseong-si (KR); Hyoc-min YOUN, Hwaseong-si (KR); SANG HOON LEE, Hwaseong-si (KR)

(73) Assignee: Samsung Display Co., Ltd., Yongin-City (KR)

(21) Appl. No.: 14/187,536

(22) Filed: Feb. 24, 2014

(30) Foreign Application Priority Data
Feb. 27, 2013 (KR) 10-2013-0021234
Oct. 24, 2013 (KR) 10-2013-0127433

(51) Int. Cl. H01L 27/32; C08K 5/12; C08K 5/06

(52) U.S. Cl. CPC H01L 27/3258; C08K 5/06; C08K 5/12
USPC 349/86; 522/47; 257/72; 438/30

(57) ABSTRACT

A photosensitive resin composition comprises about 10 wt % to about 50 wt % of a solute comprising about 100 parts by weight of an acryl-based copolymer and about 5 to about 100 parts by weight of a 1,2-quinonediazide compound; and a solvent comprising a glycol-based material having a boiling point of greater than about 190° C., wherein the acryl-based copolymer is a copolymer of an unsaturated carbonic acid or an anhydride thereof, an epoxy group-containing unsaturated compound, and an olefin-based unsaturated compound.

This application claims priority to Korean Patent Application No. 10-2013-0021234, filed on Feb. 27, 2013, and Korean Patent Application No. 10-2013-0127433, filed on Oct. 24, 2013, the contents of which are in their entirety are herein incorporated by reference.

### BACKGROUND

(1) Field

The present disclosure herein relates to a photosensitive resin composition, a display device using the same, and a method of manufacturing the display device. The display device includes an organic planarization layer obtained by curing a photosensitive resin composition.

(2) Description of the Related Art

A flat display device includes a liquid crystal display device, an organic light-emitting display device, and the like. A display apparatus generally includes a display device and driving devices for driving thereof. Driving devices such as a thin film transistor may be connected to a display device, a power source and a driving part via various signal wires. For a display apparatus having a high resolution, the number of driving devices and signal wires included in the display apparatus increases and the disposal thereof becomes complicated.

On the top surface of a display apparatus, a planarization layer may be formed to provide a planar surface. The planarization layer secures the stability of elements stacked thereon and provides uniform display quality.

### SUMMARY

The present disclosure provides a photosensitive resin composition for a planarization layer having improved planarization properties.

The present disclosure also provides a display device including a planarization layer covering complicated circuit wires, and a method of manufacturing the same.

One or more exemplary embodiments, provides a photosensitive resin composition including about 10 to about 50 weight percent (wt %) of a solute including about 100 parts by weight of an acryl-based copolymer and about 5 to about 100 parts by weight of a 1,2-quinonediazide compound, and a solvent including a glycol-based material having a boiling point greater than about 190 degrees Celsius (° C.).

In exemplary embodiments, the acryl-based copolymer is a copolymer of an unsaturated carbonic acid or an anhydride thereof, an epoxy group-containing unsaturated compound, and an olefin-based unsaturated compound.

In some exemplary embodiments, the acryl-based copolymer includes about 5 to about 45 parts per weight of the unsaturated carbonic acid or the anhydride thereof, about 10 to about 70 parts by weight of the epoxy group-containing unsaturated compound, and about 10 to about 70 parts by weight of the olefin-based unsaturated compound.

In other exemplary embodiments, the solvent includes at least one of diethylene glycol butyl methyl ether, diethylene glycol butyl ethyl ether, triethylene glycol dimethyl ether, triethylene glycol butyl methyl ether, diethylene glycol tert-butyl ether, tetraethylene glycol dimethyl ether, dipropylene glycol diethyl ether, diethylene glycol ethyl hexyl ether, diethylene glycol methyl hexyl ether, dipropylene glycol butyl methyl ether, dipropylene glycol ethyl hexyl ether, and dipropylene glycol methyl hexyl ether.

In still other exemplary embodiments, the solvent further includes at least one of an alcohol, an ethylene glycol alkyl ether acetate, an ethylene glycol alkyl ether propionate, an ethylene glycol monoalkyl ether, an propylene glycol alkyl ether propionate, a propylene glycol monoalkyl ether, dipropylene glycol dimethyl ether, diethylene glycol methyl ethyl ether, methyl beta-methoxy propionate, and ethyl beta-ethoxy propionate.

In even other exemplary embodiments, an amount of the glycol-based material is at least about 5 wt % based on 100 wt % of the photosensitive resin composition.

In yet other exemplary embodiments, the photosensitive resin composition further includes about 0.0001 to about 10 parts by weight of a plasticizer based on about 100 parts by weight of the acryl-based copolymer.

In further embodiments, the plasticizer includes at least one of dioctyl phthalate, diisononyl phthalate, dioctyl adipate, tricresyl phosphate, 2,2,4-trimethyl-1,3-pentanediol monoisobutyrate, and 2,2,4-trimethyl-1,3-pentanediol diisobutyrate.

In one or more exemplary embodiments, display devices include a first base substrate including a transparent area, a shielding area adjacent to the transparent area, and a plurality of signal wires in the shielding area, a planarization layer overlapping the transparent area and the shielding area and covering the plurality of signal wires, where the planarization layer includes a cured product of a photosensitive resin composition, and a pixel electrode on the planarization layer and overlapping the transparent area.

In exemplary embodiments, the photosensitive resin composition includes about 10 to about 50 wt % of a solute including about 100 parts by weight of an acryl-based copolymer and about 5 to about 100 parts by weight of a 1,2-quinonediazide compound, and a solvent including a glycol-based material having a boiling point of higher than about 190° C.

In exemplary embodiments, the acryl-based copolymer is a copolymer of an unsaturated carbonic acid or an anhydride thereof, an epoxy group-containing unsaturated compound, and an olefin-based unsaturated compound.

In some exemplary embodiments, the photosensitive resin composition further includes about 0.0001 to about 10 parts by weight of a plasticizer based on about 100 parts by weight of the acryl-based copolymer.

In other exemplary embodiments, the display device further includes a thin film transistor disposed in the shielding area, such that the thin film transistor is connected to a signal wire among the plurality of signal wires and to the pixel electrode, and the planarization layer covers the thin film transistor.

In still other exemplary embodiments, the planarization layer includes at least one step on a top surface thereof, where a height of the step is less than about 5,000 angstroms (Å) as measured by a distance between a top surface of the first base substrate and a top surface of the step of the planarization layer.

In even other exemplary embodiments, the planarization layer may have at least one color.

In yet other exemplary embodiments, the display device further includes a second base substrate disposed above the first base substrate and facing the first base substrate, at least one color pattern on the second base substrate and overlapping the transparent area, of the first base substrate and a black matrix adjacent to the color pattern and overlapping the shielding area of the first base substrate.

In further exemplary embodiments, the display device further includes a liquid crystal layer encapsulated between the first base substrate and the second base substrate, and disposed on the pixel electrode, such that the liquid crystal layer covers at least one step of the planarization layer.

In still other exemplary embodiments, methods of manufacturing a display device include forming a first display substrate, and forming a second display substrate on the first display substrate. The forming of the first substrate includes forming a first base substrate including a plurality of signal wires, and a thin film transistor connected to a signal wire among the plurality of signal wires, coating a layer including a photosensitive resin composition on the first base substrate to cover the plurality of signal wires and the thin film transistor, forming an planarization layer by curing the photosensitive resin composition, and forming a pixel electrode electrically connected to the thin film transistor, on the planarization layer. The photosensitive resin composition includes about 10 to about 50 wt % of a solute including about 100 parts by weight of an acryl-based copolymer and about 5 to about 100 parts by weight of a 1,2-quinonediazide compound, and a solvent including a glycol-based material having a boiling point of higher than about 190° C. The acryl-based copolymer is with a copolymer of an unsaturated carbonic acid or an anhydride thereof, an epoxy group-containing unsaturated compound, and an olefin-based unsaturated compound

In some exemplary embodiments, the glycol-based material includes at least one of diethylene glycol butyl methyl ether, diethylene glycol butyl ethyl ether, triethylene glycol dimethyl ether, triethylene glycol butyl methyl ether, diethylene glycol tert-butyl ether, tetraethylene glycol dimethyl ether, dipropylene glycol diethyl ether, diethylene glycol ethyl hexyl ether, diethylene glycol methyl hexyl ether, dipropylene glycol butyl methyl ether, dipropylene glycol ethyl hexyl ether, and dipropylene glycol methyl hexyl ether.

In other exemplary embodiments, an amount of the glycol-based material is at least about 5 wt % based on the photosensitive resin composition.

In still other exemplary embodiments, the forming of the planarization layer includes removing the solvent and curing the photosensitive resin composition.

In even other exemplary embodiments, the forming of the second display substrate includes forming a second base substrate, forming a black matrix on the second base substrate, and forming an opening part overlapping the pixel electrode, and forming a common electrode on the black matrix.

In yet other exemplary embodiments, the method of manufacturing a display device further includes combining the first display substrate and the second display substrate, and injecting liquid crystal between the first display substrate and the second display substrate.

According to the above description, the method of manufacturing a display substrate includes forming a planarization layer using a photosensitive resin composition including a glycol-based solvent having a high boiling point. The glycol-based solvent having a high boiling point may contribute to forming a planarization layer having good planarization properties without extending a process time for forming the planarization layer. Thus, even though an area in which the number of signal wires or devices is disposed increases, a relatively planar top surface may be provided, and a display substrate having improved display quality and high resolution may be manufactured.

In addition, in the method of manufacturing a display device including the above-described display substrate, a uniformly disposed liquid crystal layer in a large area may be formed. The processing time of the method of manufacturing a display device may decrease, and a display device having uniform planarity, and improved sensitivity, resolution, and contrast ratio may be provided.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain principles of the invention. In the drawings:

FIG. 1 is a block diagram of an exemplary embodiment of a display device according to the invention;

FIG. 2 is a perspective view of the display panel in FIG. 1;

FIG. 3 is a partial plan view of an exemplary embodiment of a display panel according to the invention;

FIG. 4 is a partial cross-sectional view of an exemplary embodiment of a display panel according to the invention;

FIG. 5 is a partial cross-sectional view of an exemplary embodiment of a display panel according to the invention; and

FIGS. 6A to 6H are cross-sectional views illustrating a method of manufacturing an exemplary display panel according to the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

In exemplary embodiments, a photosensitive resin composition includes about 10 to about 50 weight percent (wt %) of a solute including about 100 parts by weight of an acryl-based copolymer, about 5 to about 100 parts by weight of a 1,2-quinonediazide compound, and a solvent including a glycol-based material.

The acryl-based copolymer includes a copolymer of an unsaturated carbonic acid or an anhydride thereof, an epoxy group-containing unsaturated compound, and an olefin-based unsaturated compound. The acryl-based copolymer is synthesized by copolymerizing the unsaturated carbonic acid or the anhydride thereof, the epoxy group-containing unsaturated compound, and the olefin-based unsaturated compound in a solvent for copolymerization in the presence of a polymerization initiator.

The unsaturated carbonic acid, the anhydride thereof, or a mixture thereof may include an unsaturated monocarbonic acid such as acrylic acid, methacrylic acid, etc.; an unsaturated dicarbonic acid such as maleic acid, fumaric acid, citraconic acid, methaconic acid, itaconic acid, etc.; or an anhydride of the unsaturated dicarbonic acid, etc. These compounds may be used alone or a combination of two or more thereof may be used. In particular, the acrylic acid, the methacrylic acid, or maleic anhydride may be used when considering the copolymerization reactivity and the solubility in an aqueous alkaline solution, that is, a developing solution.

The amount of the unsaturated carbonic acid, the unsaturated carbonic acid anhydride or the mixture thereof may be about 5 to about 45 parts by weight based on the total amount of monomers. Within the above range, the solubility of the aqueous alkaline solution may be improved.

The epoxy group-containing unsaturated compound may include glycidyl acrylate, glycidyl methacrylate, glycidyl α-ethyl acrylate, glycidyl αn-propyl acrylate, glycidyl α-n-butyl acrylate, β-methyl glycidyl acrylate, β-methyl glycidyl methacrylate, β-ethyl glycidyl acrylate, β-ethyl glycidyl methacrylate, 3,4-epoxy butyl acrylate, 3,4-epoxy butyl methacrylate, 6,7-epoxy heptyl acrylate, 6,7-epoxy heptyl methacrylate, 6,7-epoxy heptyl α-ethyl acrylate, o-vinylbenzyl glycidyl ether, m-vinylbenzyl glycidyl ether, p-vinylbenzyl glycidyl ether, 3,4-epoxy cyclohexyl methacrylate, and the like. These compounds may be used alone or a mixture of two or more thereof may be used.

In particular, the epoxy group-containing unsaturated compound may be at least one of glycidyl methacrylate, β-methyl glycidyl methacrylate, 6,7-epoxy heptyl methacrylate, o-vinylbenzyl glycidyl ether, m-vinylbenzyl glycidyl ether, p-vinylbenzyl glycidyl ether, and 3,4-epoxy cyclohexyl methacrylate. In this case, the copolymerization reactivity of the epoxy group-containing unsaturated compound may be improved and the heat resistance of a pattern may be improved.

The epoxy group-containing compound may be present in an amount of about 10 to about 70 parts by weight based on the total amount of the monomers. In this case, the heat resistance and the storage stability of the photosensitive resin composition may be improved.

The olefin-based unsaturated compound may include methyl methacrylate, ethyl methacrylate, n-butyl methacrylate, sec-butyl methacrylate, tert-butyl methacrylate, methyl acrylate, isopropyl acrylate, cyclohexyl methacrylate, 2-methylcyclohexyl methacrylate, dicyclopentenyl acrylate, dicyclopentanyl acrylate, dicyclopentenyl methacrylate, dicyclopentanyl methacrylate, 1-adamantyl acrylate, 1-adamantyl methacrylate, dicyclopentanyl oxyethyl methacrylate, isobornyl methacrylate, cyclohexyl acrylate, 2-methylcyclohexyl acrylate, dicyclopentanyl oxyethyl acrylate, isobornyl acrylate, phenyl methacrylate, phenyl acrylate, benzyl acrylate, 2-hydroxyethyl methacrylate, styrene, o-methylstyrene, m-methylstyrene, p-methylstyrene, vinyl toluene, p-methoxystyrene, 1,3-butadiene, isoprene, 2,3-dimethyl 1,3-butadiene, and the like. These compounds may be used alone or a mixture of two or more may be used.

In an exemplary embodiment, the olefin-based unsaturated compound may be styrene, dicyclopentanyl methacrylate, or p-methoxystyrene. In this case, the copolymerization reactivity of the olefin-based unsaturated compound may increase, and the solubility with respect to the aqueous alkaline solution may be improved. Thus, a developing process may be easily performed.

The amount of the olefin-based unsaturated compound may be about 10 to about 70 parts by weight based on the amount of the total monomers. Within the above range, swelling may not be generated while performing the developing process, and the solubility of an aqueous alkaline solution that is the developing solution, may be ideally maintained.

The solvent for copolymerization of the monomers may include methanol, tetrahydroxyfuran, toluene, dioxane, and the like. The polymerization initiator may be a radical polymerization initiator, including, for example, 2,2-azobisisobutyronitrile, 2,2-azobis(2,4-dimethylvaleronitrile), 2,2-azobis(4-methoxy 2,4-dimethylvaleronitrile), 1,1-azobis(cyclohexane-1-carbonitrile), dimethyl 2,2′-azobisisobutyrate, and the like.

After precipitating and filtering the radical synthesized solution, unreacted monomers are removed through a drying process in a vacuum state, and the acryl-based copolymer is obtained. In this case, the polystyrene converted weight average molecular weight (Mw) of the acryl-based copolymer may be about 5,000 to about 30,000 grams per mole (g/mol).

As the 1,2-quinonediazide compound, known compounds used in the photosensitive resin composition may be used, including for example, 1,2-quinonediazide 4-sulfonic acid ester, 1,2-quinonediazide 5-sulfonic acid ester, 1,2-quinonediazide 6-sulfonic acid ester, and the like.

In exemplary embodiments, the photosensitive resin composition may include a solvent in an amount such that the solid content in the photosensitive resin composition is about 10 to about 50 wt %. The solvent may include a glycol-based material having a high boiling point. The glycol-based material having a high boiling point refers to a glycol-based material having a boiling point of about 190 degrees Celsius (° C.) to about 1,000° C.

In an exemplary embodiment, the solvent includes at least one of diethylene glycol butyl methyl ether, diethylene glycol butyl ethyl ether, triethylene glycol dimethyl ether, triethylene glycol butyl methyl ether, diethylene glycol tert-butyl ether, tetraethylene glycol dimethyl ether, dipropylene glycol diethyl ether, diethylene glycol ethyl hexyl ether, diethylene glycol methyl hexyl ether, dipropylene glycol butyl methyl ether, dipropylene glycol ethyl hexyl ether, diethylene glycol monomethyl ether, diethylene glycol monoethyl ether, and dipropylene glycol methyl hexyl ether.

The solvent may further include other materials. For example, the solvent may further include at least one of an alcohol, such as methanol, ethanol, benzyl alcohol, and hexyl alcohol; an ethylene glycol alkyl ether acetate, such as ethylene glycol methyl ether acetate, and ethylene glycol ethyl ether acetate; an ethylene glycol alkyl ether propionate, such as ethylene glycol methyl ether propionate, and ethylene glycol ethyl ether propionate; an ethylene glycol monoalkyl ether, such as ethylene glycol methyl ether, and ethylene glycol ethyl ether; a propylene glycol alkyl ether propionate, such as propylene glycol methyl ether acetate, propylene glycol ethyl ether acetate, propylene glycol propyl ether acetate, propylene glycol methyl ether propionate, propylene glycol ethyl ether propionate, and propylene glycol propyl ether propionate; a propylene glycol monoalkyl ether, such as propylene glycol methyl ether, propylene glycol ethyl ether, propylene glycol propyl ether, and propylene glycol butyl ether; dipropylene glycol dimethyl ether, diethylene glycol methyl ethyl ether, methyl beta-methoxy propionate, and ethyl beta-ethoxy propionate. In this case, the glycol-based material having a high boiling point may be at least about 5 wt % based on the total amount of the photosensitive resin composition.

The photosensitive resin composition may be applied using various processes such as printing, patterning, etc. In exemplary embodiments, the photosensitive resin composition may be used in a process for manufacturing a display apparatus. The photosensitive resin composition may be cured and used for forming a planarization layer or a patterning mask.

In exemplary embodiments, a planarization layer formed using the photosensitive resin composition may have improved planarization properties and may form a uniform surface. Through the inclusion of the glycol-based material in the solvent, the planarization properties of the planarization layer may be improved, and the generation of coating stain may be restrained, thereby forming a uniform pattern profile.

In other exemplary embodiments, the photosensitive resin composition may further include a plasticizer. The amount of the plasticizer may be about 0.0001 to about 10 parts by weight based on about 100 parts by weight of the acryl-based copolymer of the photosensitive resin composition. The plasticizer improves the processability of the photosensitive resin composition. The plasticizer may include at least one of dioctyl phthalate, diisononyl phthalate, dioctyl adipate, tricresyl phosphate, 2,2,4-trimethyl-1,3-pentanediol monoisobutyrate, and 2,2,4-trimethyl-1,3-pentanediol diisobutyrate.

In exemplary embodiments, the photosensitive resin composition may further include an adhesive. The adhesive may improve the adhesiveness of the photosensitive resin composition with the substrate. The adhesive may be included in the photosensitive resin composition in an amount of about 0.01 wt % to about 10 wt % based on the total amount of the photosensitive resin composition.

The adhesive may be a silane coupling agent having a reactive substituent such as a carboxyl group, a methacryl group, an isocyanate group, an epoxy group, and the like. The silane coupling agents such as γ-methacryloxypropyltrimethoxysilane, vinyltriacetoxysilane, vinyltrimethoxysilane, γ-isocyanatepropyltriethoxysilane, γ-glycidoxypropyltrimethoxysilane, γ-(3,4-epoxycyclohexyl)ethyltrimethoxysilane, and the like may be used.

In additional exemplary embodiments, the photosensitive resin composition may further include a surfactant. The surfactant may improve the step coverage or the developing properties of the photosensitive resin composition. The photosensitive resin composition may selectively include any one among the surfactant and the adhesive.

The surfactant may include polyoxyethylene octyl phenyl ether, polyoxyethylene nonyl phenyl ether, F171, F172, F173 (trade name: manufactured by Dai Nippon Ink and Chemicals, Inc.), FC430, FC431 (trade name: manufactured by Sumitomo 3M, Ltd.), KP341 (trade name: manufactured by Shin-Etsu chemical Co., Ltd.), and the like.

The surfactant may be included in an amount of about 0.0001 wt % to about 2 wt % based on the total weight of the photosensitive resin composition. In this case, the photosensitive resin composition may have improved step coverage, and better developing properties.

In one or more exemplary embodiments, the photosensitive resin composition has good adhesiveness, heat resistance, insulating properties, planarity, chemical resistance, and the like, and is appropriate as a material for forming an image of a liquid crystal display device. In particular, when forming an insulating layer for a liquid crystal display device, the sensitivity, remaining rate, resolution, or contrast ratio of the liquid crystal display device may be good, and the cured photosensitive resin composition may be effective as an planarization layer in a liquid crystal display device.

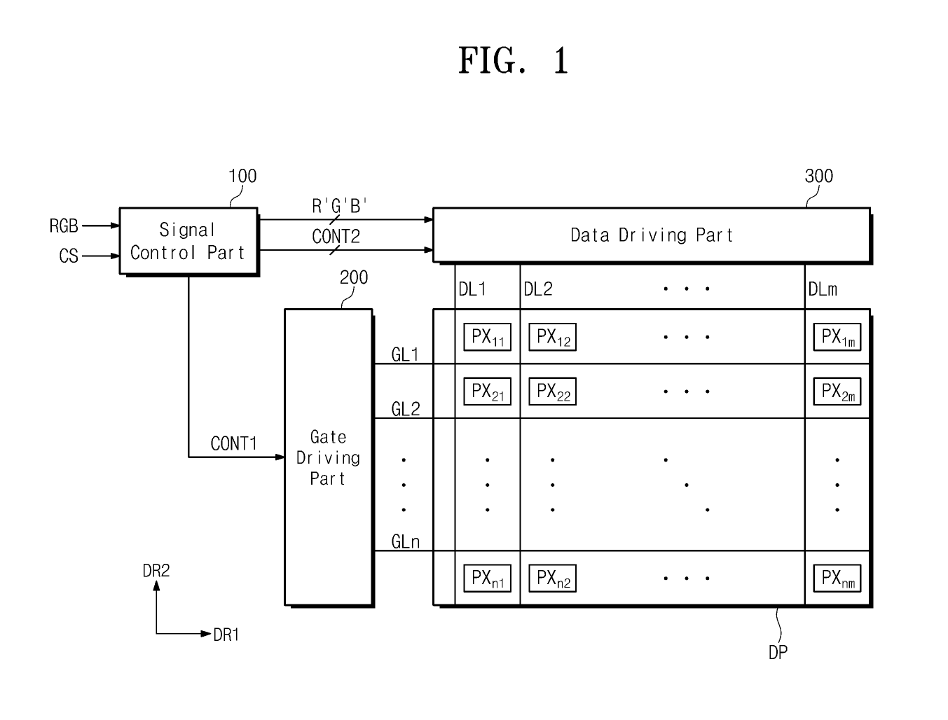

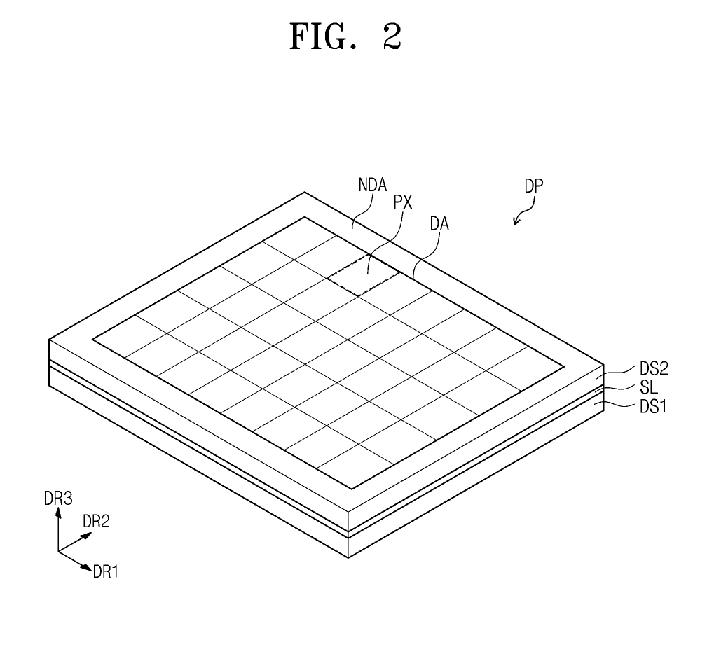

Hereinafter exemplary embodiments related to the planarization layer of a liquid crystal display device will be described in detail referring to FIGS. 1 and 2.

FIG. 1 is a block diagram of an exemplary display device, and FIG. 2 is a perspective view of a display panel in FIG. 1. As shown in FIG. 1, the display device includes a signal control part 100, a gate driving part 200, a data driving part 300, and a display panel DP.

The signal control part 100 receives input image signals RGB, and the input image signals RGB are converted into image data R′G′B′ coinciding with the operation of the display panel DP. The signal control part 100 receives various control signals CS and outputs first and second control signals CONT1 and CONT2, respectively. The control signal CS may be, for example, a vertical synchronization signal, a horizontal synchronization signal, a main clock signal, a data enable signal, and the like.

The gate driving part 200 outputs gate signals to the display panel DP in response to the first control signal CONT1. The first control signal CONT1 includes a vertical initiation signal initiating the operation of the gate driving part 200, a gate clock signal determining the output time of a gate voltage, and an output enable signal determining the on pulse width of the gate voltage.

The data driving part 300 receives the second control signal CONT2 and the image data R′G′B′. The data driving part 300 converts the image data R′G′B′ into a data voltage and provides thereof to the display panel DP.

The second control signal CONT2 includes a horizontal initiation signal initiating the operation of the data driving part 300, a reverse signal reversing the polarity of the data voltages, and an output indicating signal determining the output time of the data voltages from the data driving part 300.

The display panel DP includes a plurality of signal wires and a plurality of pixels PX₁₁-PXₙₘ connected to the plurality of the signal wires. The plurality of the signal wires includes a plurality of gate lines GL₁-GLₙ, and a plurality of data lines DL₁-DLₘ.

The plurality of gate lines GL₁-GLₙ is extended in a first direction DR1 and arranged in a second direction DR2 crossing the first direction DR1. The plurality of gate lines GL₁-GLₙ is connected to the gate driving part 200. The plurality of gate lines GL₁-GLₙ receives gate signals from the gate driving part 200.

The plurality of data lines DL₁-DLₘ cross, and is insulated from, the plurality of gate lines GL₁-GLₙ. The plurality of data lines DL₁-DLₘ are connected to the data driving part 300. The plurality of data lines DL₁-DLₘ receive data voltages from the data driving part 300.

The plurality of the signal wires may further include at least one common line (not shown). The common line receives a reference voltage. The reference voltage may be the same voltage applied to a common electrode CE which will be described hereinafter.

The plurality of the pixels PX₁₁-PXₙₘ may be arranged in a matrix. Each of the plurality of pixels PX₁₁-PXₙₘ is connected to a corresponding gate line among the plurality of gate lines GL₁-GLₙ and to a corresponding data line corresponding to the plurality of data lines DL₁-DLₘ.

The type of display panel DP is not specifically limited, and may include, for example, an organic light-emitting display panel, a liquid crystal display panel, a plasma display panel, an electrophoretic display panel, an electrowetting display panel, and the like.

The display panel DP may be divided into a display area DA and a non-display area NDA adjacent to the display area DA on a plane. In the display area DA, the plurality of pixels PX₁₁-PXₙₘ is disposed. In the non-display area NDA, the plurality of signal wires, the gate driving part 200 and the data driving part 300 may be disposed.

In an embodiment according to the invention, a liquid crystal display device including a liquid crystal display panel will be explained as an illustration. The liquid crystal display panel includes two display substrates DS1 and DS2, and a liquid crystal layer (not shown) disposed between the two display substrates DS1 and DS2. In an exemplary embodiment, each of the substrates DS1 and DS2 may be an independent display substrate.

The plurality of gate lines GL₁-GLₙ, the plurality of the data lines DL₁-DLₘ, and the plurality of pixels PX₁₁-PXₙₘ shown in FIG. 1 are disposed on one of the first substrate DS1 and the second substrate DS2. The first substrate DS1 and the second substrate DS2 are separated in the thickness direction DR3 (hereinafter referred to as a “third” direction) of the display substrates.

Between the first substrate DS1 and the second substrate DS2, a seal member SL is disposed. The seal member SL may overlap with the non-display area NDA. The seal member SL may combine the first substrate DS1 and the second substrate DS2, and encapsulate the liquid crystal layer (not shown) between the first substrate DS1 and the second substrate DS2.

The liquid crystal display device further includes a backlight unit (not shown) providing a light to the display panel DP. The liquid crystal display panel may have a mode selected from a vertical alignment (“VA”) mode, a patterned vertical alignment (“PVA”) mode, an in-plane switching (“IPS”) mode, a fringe-field switching (“FFS”) mode, and a plane to line switching (“PLS”) mode, however the liquid crystal display panel is not limited to a panel of a specific mode.

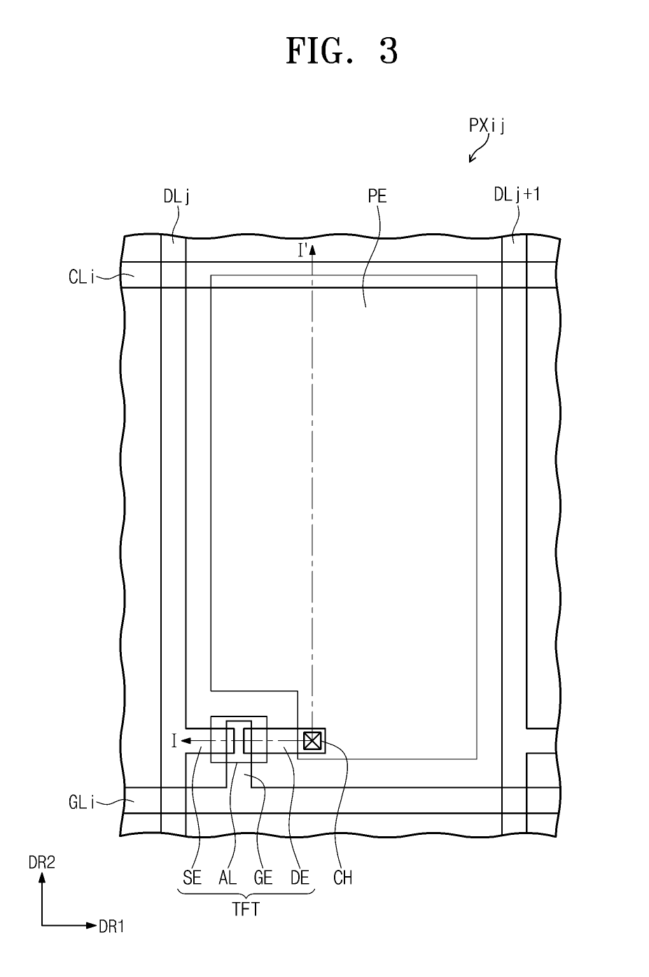

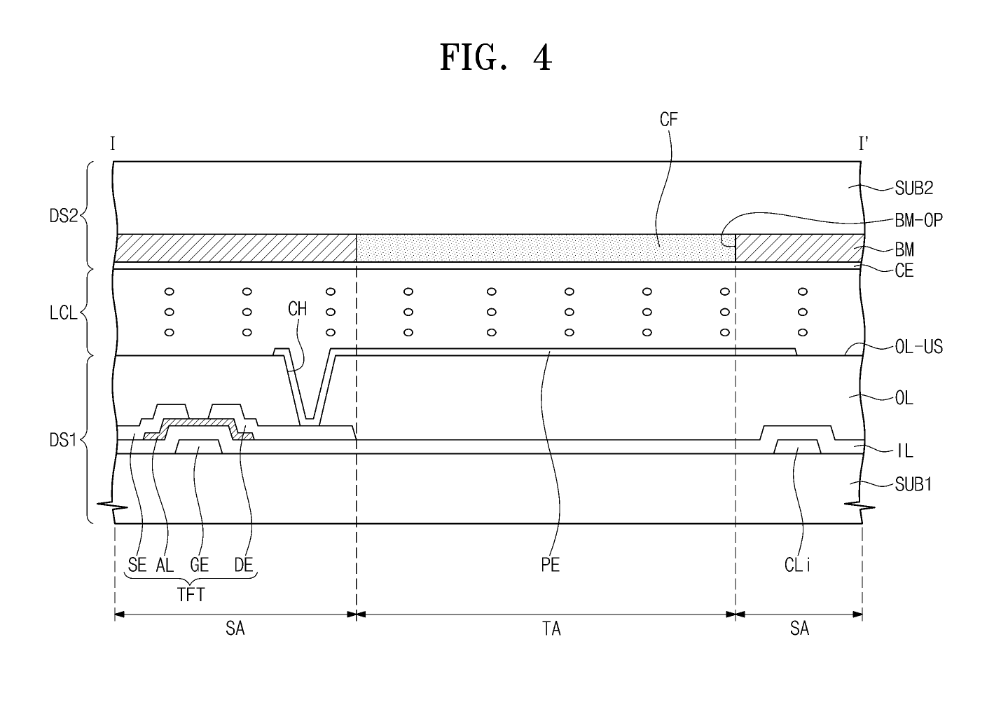

FIG. 3 is a partial plan view of an exemplary embodiment of a display panel DP, . FIG. 4, is a cross-sectional view taken along line I-I′ of the display panel DP in FIG. 3. In this embodiment, the plurality of gate lines GL₁-GLₙ, the plurality of data lines DL₁-DLₘ, and the plurality of pixels PX₁₁-PXₙₘ are disposed on the first substrate DS1. For convenience of explanation, the plan view of the first substrate DS1 is illustrated in FIG. 3.

The first substrate DS1 includes a first base substrate SUB1, a gate line GLᵢ, data lines DLⱼ and DLⱼ₊₁, a common line CLᵢ, and a pixel PXᵢⱼ.

In FIGS. 3 and 4, in an embodiment, the pixel PXᵢⱼ connected to the i-th gate line GLᵢ and the j-th data line DLⱼ among the plurality of the pixels PX₁₁-PXₙₘ (See FIG. 1) is illustrated. The pixel PXᵢⱼ includes a thin film transistor TFT, and a pixel electrode PE connected to the thin film transistor TFT.

The thin film transistor TFT is connected to the i-th gate line GLᵢ and the j-th data line DL_{A}. The thin film transistor TFT outputs to the pixel electrode PE a data voltage applied to the j-th data line DLⱼ in response to a gate signal applied to the i-th gate line GLᵢ. The pixel electrode PE receives a pixel voltage responding to the data voltage. The plurality of pixels PX₁₁-PXₙₘ may have the same constitution as the pixel PXᵢⱼ. In addition, the constitution of the pixel PXᵢⱼ may be changed.

The first base substrate SUB1 may be an insulating substrate such as a glass substrate, a plastic substrate, a silicon substrate, and the like. In addition, the first base substrate SUB1 may be a transparent substrate. The gate electrode GE of the thin film transistor TFT and the i-th gate line GLᵢ are disposed on the first base substrate SUB1. The gate electrode GE is connected to the i-th gate line GLᵢ.

The gate electrode GE may be formed by using the same material as the i-th gate line GLᵢ and have the same layer structure, such as being disposed in a same layer. The gate electrode GE and the i-th gate line GLᵢ include at least one of copper (Cu), aluminum (Al), an alloy thereof, and an alloy of Cu and Al. The gate electrode GE and the i-th gate line GLᵢ may have a multi layer structure including an aluminum layer and another metal layer.

The common line CLᵢ may be disposed in and/or on the same layer as the i-th gate line GLᵢ. The common line CLᵢ may be formed by using the same material as the i-th gate line GLᵢ and have the same layer structure. However, the common line CLᵢ may optionally be omitted.

On the first base substrate SUB1, an insulating layer IL covering the gate electrode GE, the i-th gate line GLᵢ, and the common line CLᵢ is disposed. On the insulating layer IL, a semiconductor layer AL overlapping the gate electrode GE is disposed. The insulating layer IL may be explained as a gate insulating layer.

On the insulating layer IL, the data lines DLⱼ and DLⱼ₊₁ are disposed. The data lines DLⱼ and DLⱼ₊₁ include at least one of copper (Cu), aluminum (Al), an alloy thereof, and an alloy of Cu and Al. The data lines DLⱼ and DLⱼ₊₁ may have a multi layer structure including an aluminum layer and another metal layer such as chromium or molybdenum.

On the insulating layer IL, a source electrode SE and a drain electrode DE of the thin film transistor TFT are disposed. The source electrode SE is connected to the j-th data line DLⱼ among the data lines DLⱼ and DLⱼ₊₁. The source electrode SE may be formed using the same material as the data lines DLⱼ and DLⱼ₊₁ and have the same layer structure.

The source electrode SE and the drain electrode DE are separated from each other. Each of the source electrode SE and the drain electrode DE partially overlaps with the semiconductor layer AL.

On the insulating layer IL, an planarization layer OL is disposed. The planarization layer OL covers the source electrode SE, the drain electrode DE, and the data lines DLⱼ and DLⱼ₊₁. The planarization layer OL planarizes the upper portion of the thin film transistor TFT and the common line CLᵢ. The planarization layer OL is formed using a photosensitive resin composition. The photosensitive resin composition includes a glycol-based solvent having a high boiling point as a solvent. Detailed description on the planarization layer will be described below.

The pixel electrode PE is disposed on the planarization layer. The pixel electrode PE is connected to the drain electrode DE through a contact hole CH defined in the planarization layer OL. An inorganic insulating layer (not shown) disposed between the planarization layer OL and the pixel electrode PE may be further included. The inorganic insulating layer blocks moisture drainable from the planarization layer OL to passivate other elements. The inorganic insulating layer may be a passivation layer. In addition, a passivation layer (not shown) covering the pixel electrode PE and an alignment layer (not shown) may be further disposed on the planarization layer OL.

Meanwhile, the shape of the pixel electrode PE is not limited to the shape shown in FIG. 3. In another embodiment, the pixel electrode PE may include a plurality of slits defined therein. The plurality of slits divides the pixel PXᵢⱼ into a plurality of domains. The plurality of domains improve viewing angle.

The second substrate DS2 includes a second base substrate SUB2, a black matrix BM, a color filter CF, and a common electrode CE. The second base substrate SUB2 may be a transparent substrate such as a glass substrate, a plastic substrate, or a silicon substrate.

The area in which the black matrix BM is disposed may be defined as a shielding area SA. The black matrix BM includes a plurality of opening parts defined therein. In FIG. 4, one opening part BM-OP corresponding to one pixel PXᵢⱼ is shown. Substantially, the opening part BM-OP defines a transparent area TA. In the opening part, the color filter CF is disposed. Each of the color filter CF corresponds to each of the plurality of the pixels PX₁₁-PXₙₘ. The color filters disposed in the pixels PX₁₁-PXₙₘ may include different colors. For example, a portion of the color filters may have red color, another portion of the color filter may have green color, and further another portion of the color filter may have blue color.

Even though not illustrated, the planarization layer OL may include at least one color in an embodiment according to the invention. In this case, the planarization layer OL may be a color filter layer. By disposing a color filter layer on the first substrate DS1, the arrangement of the pixels is facilitated, and the manufacturing process may be simplified. In this case, the color filter CF of the second substrate DS2 may be omitted.

The common electrode CE is disposed on the black matrix BM and the color filter CF. Even though not illustrated, the second substrate DS2 may further include a planarization layer covering the black matrix BM and the color filter CF. The common electrode CE may be disposed on the planarization layer.

On the common electrode CE, a passivation layer (not shown) covering the common electrode CE and an alignment layer (not shown) may be further disposed. Meanwhile, the common electrode CE may include a plurality of slits forming a plurality of domains, and may be disposed on the first base substrate SUB1.

A liquid crystal layer LCL is disposed between the first substrate DS1 and the second substrate DS2. The liquid crystal layer LCL includes liquid crystal molecules, and alignment molecules controlling the alignment of the liquid crystal molecules. The liquid crystal molecules control the gray scale of a display panel by changing the alignment of the alignment molecules according to an electric field formed by the pixel electrode PX and the common electrode CE.

As shown in FIG. 4, the first substrate DS1 may be divided into a shielding area SA and a transparent area TA adjacent to the shielding area SA. The transparent area TA is an area through which a light emitted from a light source (not shown) is penetrated. The transparent area TA is an area in which an image is displayed.

The shielding area SA is an area in which the emitted light is blocked. The thin film transistor TFT, and the plurality of signal wires are disposed in the shielding area SA. The thin film transistor TFT and the plurality of the signal wires substantially block the emitted light.

The top (upper) surface OL-US of the planarization layer OL is substantially non-uniform in the shielding area SA. In the shielding area SA, at least one “step” may be formed at the top surface of the planarization layer OL-US. As used herein, the term “step” refers to a height difference in the top surface of the planarization layer OL-US. A height of the step is measured by a distance between a top surface of the first base substrate to a top surface of the step of the planarization layer OL-US. The step may be formed by the thin film transistor TFT and the plurality of the signal wires. On the contrary, in the transparent area TA, only the insulating layer IL is disposed on the planar first base substrate SUB1, and no devices are disposed separately. Thus, in the transparent area TA the top surface of the planarization layer OL forms a relatively uniform planar surface.

Between the top surface of the transparent area TA and the top surface of the shielding area SA, a step corresponding to the height of the thin film transistor TFT or the height of the common line CLᵢ may be formed. The height from the first base substrate SUB1 to the top surface of the planarization layer OL-US may be different in the transparent area TA as compared to the shielding area SA.

To relieve the step, the planarization layer OL is disposed. The step refers to a height difference in the top surface of the planarization layer OL-US. When the step is not relieved, the uniform formation of the liquid crystal layer LCL in the shielding area SA and the transparent area TA may be difficult, and the alignment of the alignment molecules composing the liquid crystal layer LCL may become non-uniform.

In an exemplary embodiment, the planarization layer OL is formed using a photosensitive resin composition including a glycol-based solvent having a high boiling point. The glycol-based solvent having a high boiling point includes a glycol-based material having a boiling point of greater than 190° C. The planarization layer OL planarizes the step between the shielding area SA and the transparent area TA to less than about 5,000 Å. Detailed description on embodiments will be explained herein below.

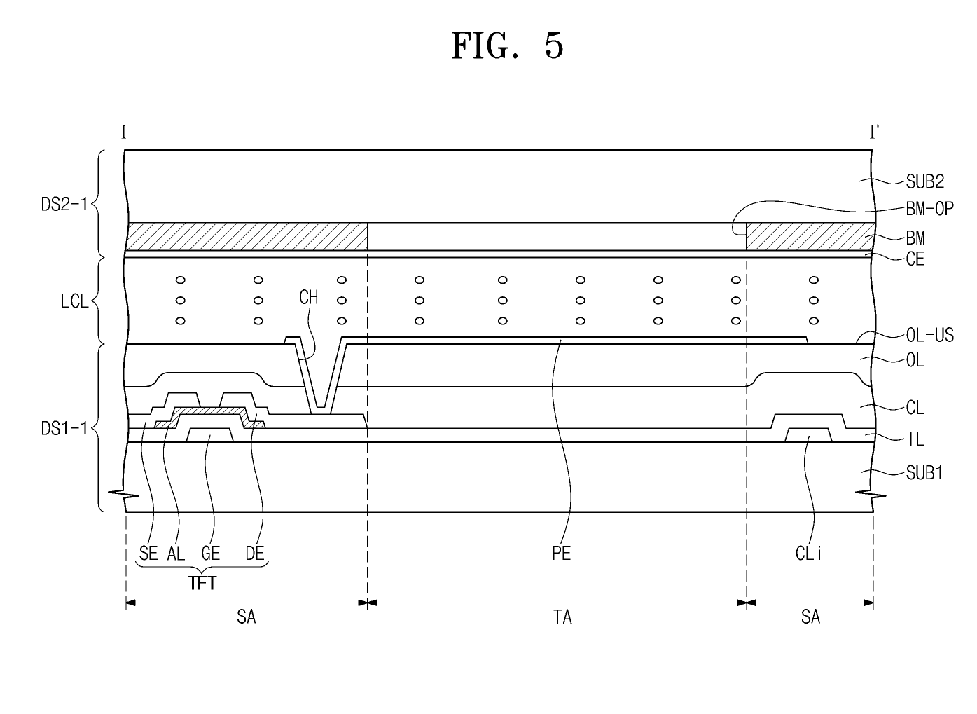

FIG. 5 is a partial cross-sectional view of an exemplary display panel. FIG. 5 illustrates a corresponding area of FIG. 4. Meanwhile, the same reference symbols in FIG. 5 refer to the same elements as those explained in FIGS. 1 to 4, and accordingly, repeated explanation will be omitted.

As shown in FIG. 5, a first substrate DS1-1 may further include a color layer CL. The color layer CL may be disposed between the insulating layer IL and the planarization layer OL.

The color layer CL corresponds to each of the plurality of pixels PX₁₁-PXₙₘ (See FIG. 1). The color layer CL may include a plurality of color patterns disposed in each of the pixels PX₁₁-PXₙₘ. The plurality of color patterns may include different colors. For example, the color layer CL may include a red color pattern, a green color pattern, or a blue color pattern.

A second substrate DS2-1 may be disposed above the first substrate DS1-1. The second substrate DS2-1 may include a black matrix BM having at least one of opening. In an exemplary embodiment, the second substrate DS2-1 may not include any color patterns. In this case, a color layer may be comprised in the first substrate DS1-1. A method of manufacturing the second substrate DS2-1 may be easier with omitting the color layer. And misalignment between the color pattern and each pixels may be decrease

In an exemplary embodiment, the planarization layer OL may provide a planar surface having high planarity even though formed into a relatively small thickness. For example, the planarization layer OL may have a thickness of less than about 3 micrometers (μm) in the transparent area TA. Generally, the planar surface becomes difficult to form as the thickness of the planarization layer OL decreases. Since the exemplary planarization layer OL disclosed herein has good planarization properties even though formed to a small thickness, a uniform planar surface may be provided without increasing the thickness of a color filter on array (“CoA”) structure in which the color layer is disposed in the shielding area.

In exemplary embodiments, the planarization layer OL is formed by the photosensitive resin composition. The planarization layer OL includes a cured photosensitive resin composition. The photosensitive resin composition includes an acryl-based copolymer, a 1,2-quinonediazide compound, and a solvent including a glycol-based material having a high boiling point. The glycol-based material having a high boiling point in this embodiment has a boiling point of at least about 190° C. A plasticizer may be included in various amounts. For example, the plasticizer may be included in an amount of about 0.0001 to about 10 parts by weight based on about 100 parts by weight of the acryl-based copolymer.

The planarization layer including the plasticizer in the above-described range may form a display panel having good uniformity, sensitivity, resolution, adhesiveness, transmittance, and contrast ratio. The plasticizer interacts with the acryl-based copolymer and the 1,2-quinonediazide compound and improves the planarization properties. Thus, a planarization layer for a large-sized ultrafine liquid crystal display device may be provided.

In exemplary embodiments, the photosensitive resin composition constituting the inventive planarization layer may further include an adhesive or an interfacial activator. The adhesive improves the adhesiveness of the planarization layer with another layer having an interface therewith, for example, an insulating layer IL (see FIG. 4) or a color layer CL (see FIG. 5). The adhesive may be included in an amount of about 0.01 wt % to about 10 wt % based on the total photosensitive resin composition. Meanwhile, the photosensitive resin composition forming the planarization layer in one or more exemplary embodiment of the invention may be used after filtering using a Millipore filter having a pore diameter of about 0.1-0.2 μm.

The planarization properties of the planarization layer may be improved by controlling the kind and the ratio of the solvents. Experimental data comparing the planarization properties of planarization layers prepared using photosensitive resin compositions including different solvents are illustrated in the following Table 1.

TABLE 1

| | | Material of planarization layer | | |
|---|---|---|---|---|
| | | R1 (first | R2 (second | R3 (third |
| | | planarization | planarization | planarization |
| | | layer) | layer) | layer) |
| Solvents | High | MEDG | DEDG | MBDG |
| (wt % | boiling | (20 wt %) | (15 wt %) | (15 wt %) |
| amount) | point | | | |
| | Low | MMP | MMP | MMP |
| | boiling | (80 wt %) | (85 wt %) | (85 wt %) |
| | point | | | |

| | | | |
|---|---|---|---|
| Boiling point (° C.) | MEDG 176° C. | DEDG 189° C. | MBDG 212° C. |
| | MMP 142° C. | MMP 142° C. | MMP 142° C. |
| Leveling step (Å) | 6727 | 6074 | 4825 |

The first planarization layer (R1) includes diethylene glycol methyl ethyl ether (“MEDG”) having a boiling point of about 176° C., the second planarization layer (R2) includes diethylene glycol diethyl ether (“DEDG”) having a boiling point of about 189° C., and the third planarization layer (R3) includes diethylene glycol butyl methyl ether (“MBDG”) having a boiling point of about 212° C.

Each of the planarization layers (R1-R3) includes a photosensitive resin composition containing a mixture solvent including methyl 3-methoxy propionate (“MMP”) as a solvent having a low boiling point. The photosensitive resin compositions including different solvents were coated on substrates and dried to form planarization layers. Then, the surface steps of the planarization layers were compared and illustrated in the above Table 1. In the Table 1, the average values of the steps formed on the top surface of the planarization layer are illustrated as the leveling step.

As the planarization properties of the organic layers increases, the leveling step decreases. The planarization properties of the organic layers are influenced by the boiling point temperature to a greater degree than by the amount of the solvent having the high boiling point. For instance, comparing the first planarization layer (R1) and the second planarization layer (R2), the first planarization layer (R1) has a higher amount of the solvent having a high boiling point, but the second planarization layer (R2), including a glycol-based solvent having a higher boiling point, has improved planarization properties.

The third planarization layer (R3) includes a glycol solvent having a high boiling point of about 212° C. When a solvent having a boiling point of at least about 190° C. is included, the planarization properties may be markedly improved. Generally, when the height of the step is less than about 5,000 angstroms (Å), negative influences on the driving and display quality of a display panel may be small. In addition, negative influences on the blur noise of liquid crystal may decrease for a surface having the leveling step of less than about 5,000 Å. As a result, the exemplary display panel may realize a liquid crystal layer uniformly formed on the whole surface of the display panel.

TABLE 2

| | | Material of planarization layer | | |
|---|---|---|---|---|
| | | R4 (fourth | R5 (fifth | R6 (sixth |
| | | planarization | planarization | planarization |
| | | layer) | layer) | layer) |
| Solvents | High | MBDG | MBDG | MBDG |
| (wt % | boiling | (0 wt %) | (5 wt %) | (15 wt %) |
| amount) | point | | | |
| | Low | PGMEA | PGMEA | PGMEA |
| | boiling | (100 wt %) | (95 wt %) | (85 wt %) |
| | point | | | |

| | | | |
|---|---|---|---|
| Boiling point (° C.) | MEDG 176° | MBDG 212° | MBDG 212° |
| | C. | C. | C. |
| | PGMEA 146° | PGMEA 146° | PGMEA 146° |
| | C. | C. | C. |
| Leveling step (Å) | 6942 | 6014 | 5183 |

In Table 2, the planarization properties of photosensitive resin compositions including various amounts of MBDG as the glycol-based solvent having a high boiling point are compared. To explain the planarization properties according to the component ratio, the fourth planarization layer (R4) excluding the glycol-based solvent having a high boiling point, the fifth planarization layer (R5) including about 5 wt % of the glycol-based solvent having a high boiling point, and the sixth planarization layer (R6) including about 15 wt % of the glycol-based solvent having a high boiling point were compared and shown. Meanwhile, propylene glycol monomethyl ether acetate (“PGMEA”) having a boiling point of about 146° C., was included in the solvent mixture.

As shown in Table 2, when comparing the fourth planarization layer (R4) excluding the glycol-based solvent having a high boiling point, the leveling step of the planarization layers (R5 and R6) including the glycol-based solvent having a high boiling point decreases markedly. In the case where the glycol-based solvent having a high boiling point is further included by about 5 wt %, the leveling step may be decreased by about 900 Å.

As described above, when the leveling step is about 5,000 Å, generally, the blur noise of the liquid crystal decreases, and the deterioration of display quality may be prevented. As shown in Table 2, in the case that the glycol-based solvent having a high boiling point is included in an amount of about 15 wt %, the average leveling step is about 5,000 Å. In the case that a planarization layer is formed using a photosensitive resin composition including the glycol-based solvent having a high boiling point, in an amount of at least about 15 wt %, a display panel having improved display quality may be realized.

In exemplary embodiments, a display panel may realize a planarization layer minimizing the step between the shielding area SA and the transparent area TA by using a photosensitive resin composition including the glycol-based solvent having a high boiling point. As a result, in a high resolution display panel having a higher percentage of the shielding area SA, the liquid crystal may be more uniformly distributed, and the display quality may be improved.

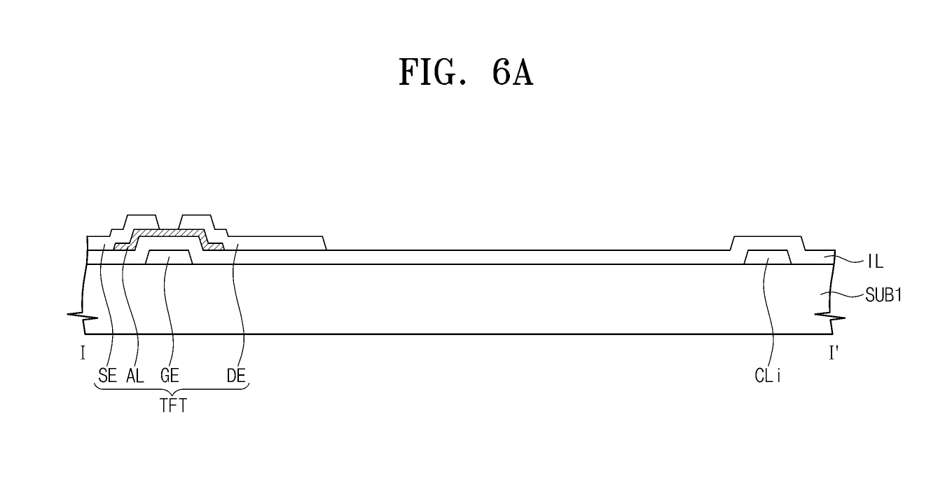

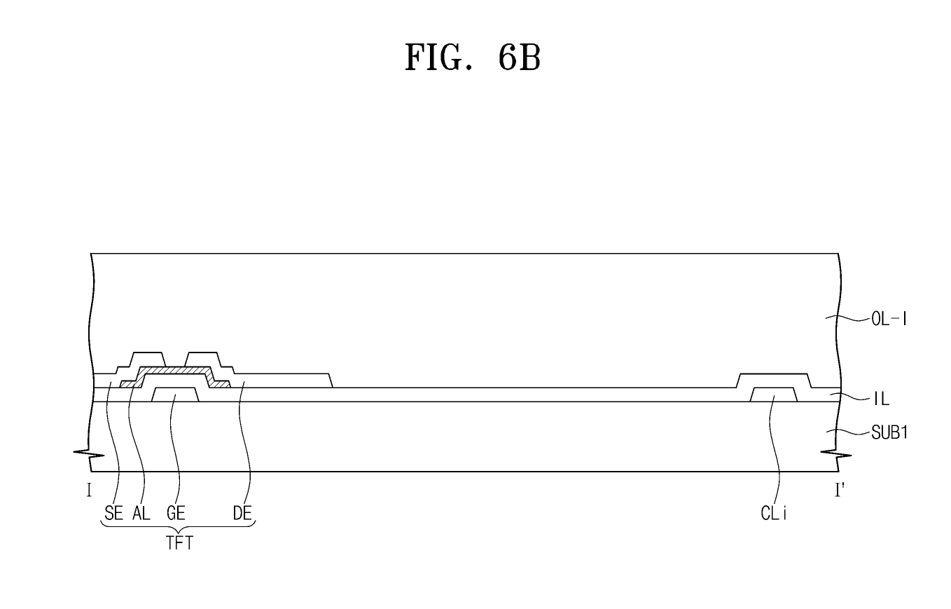

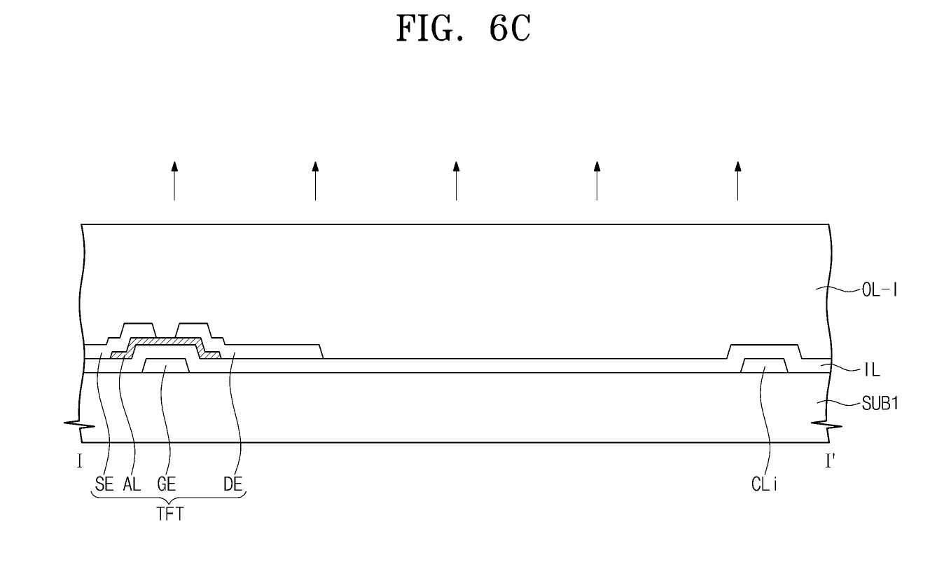

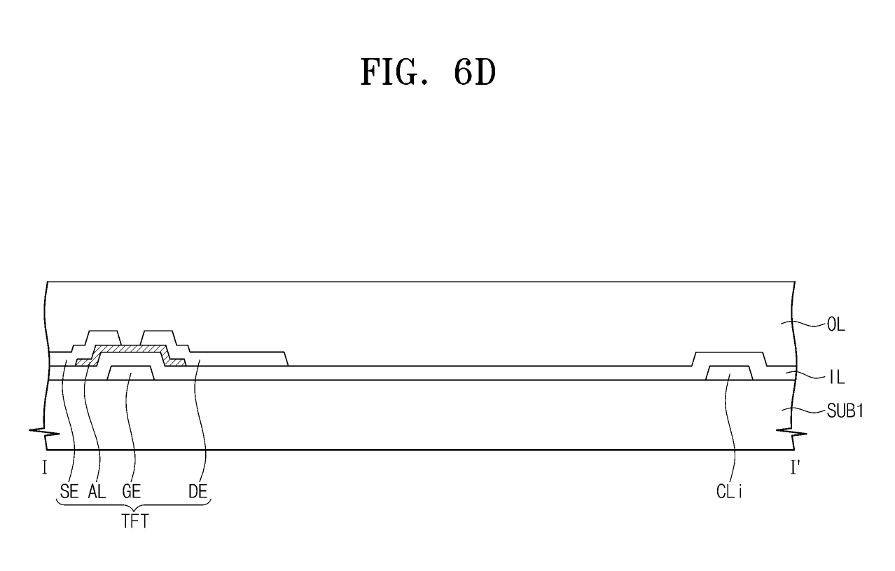

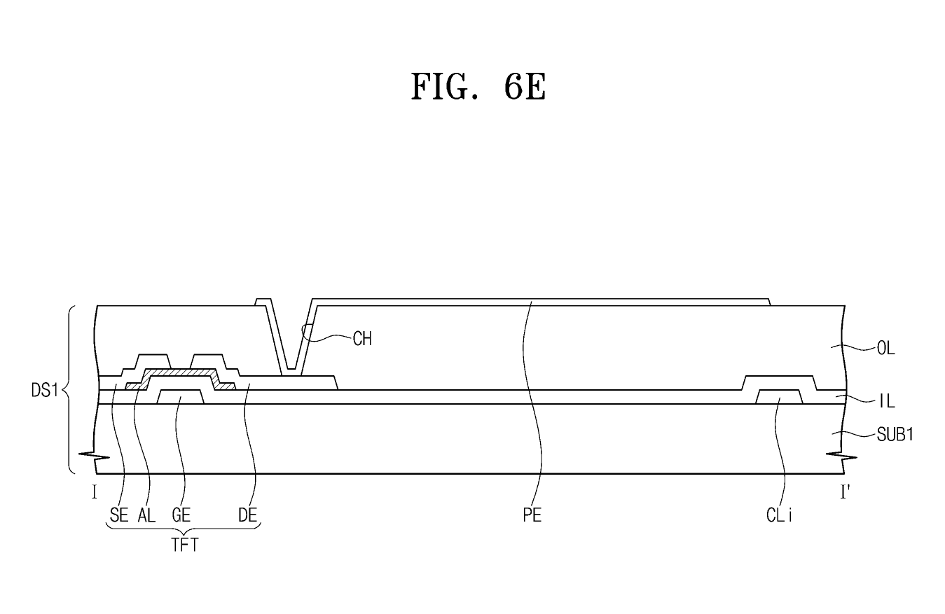

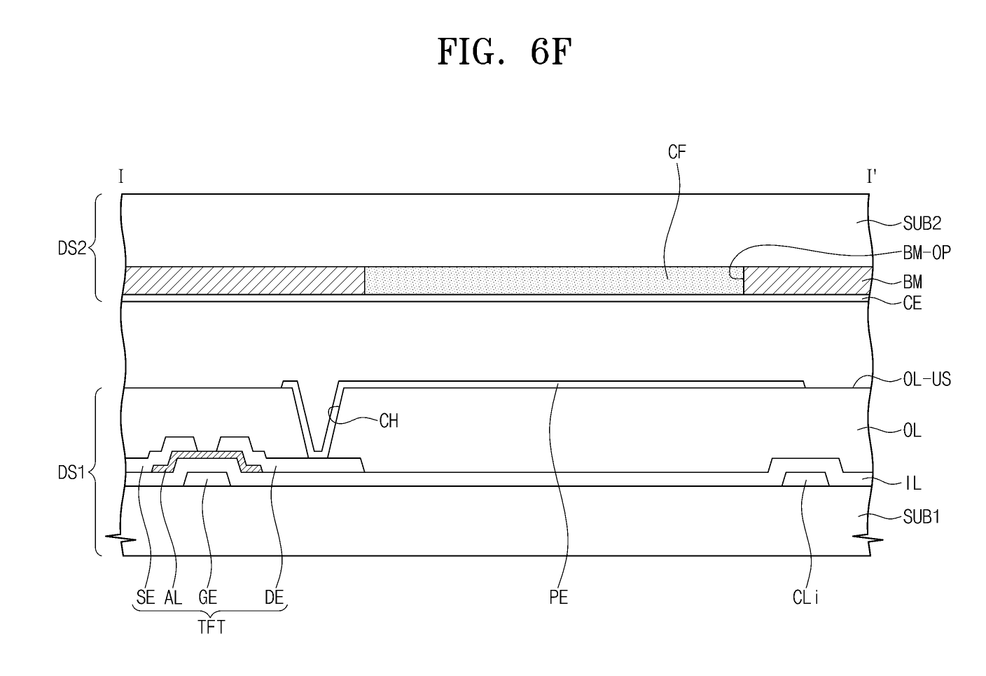

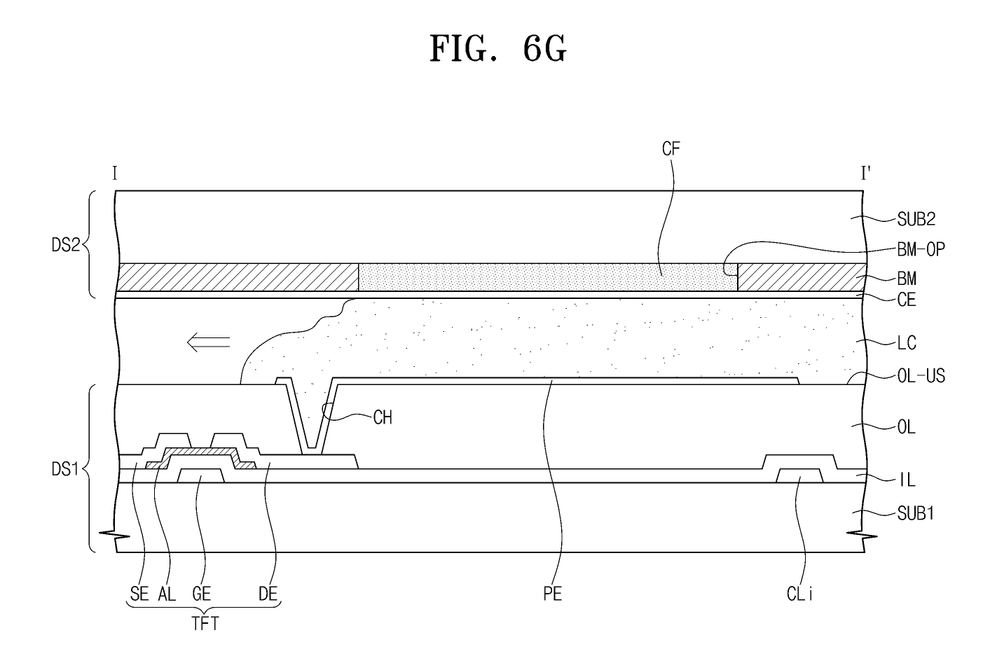

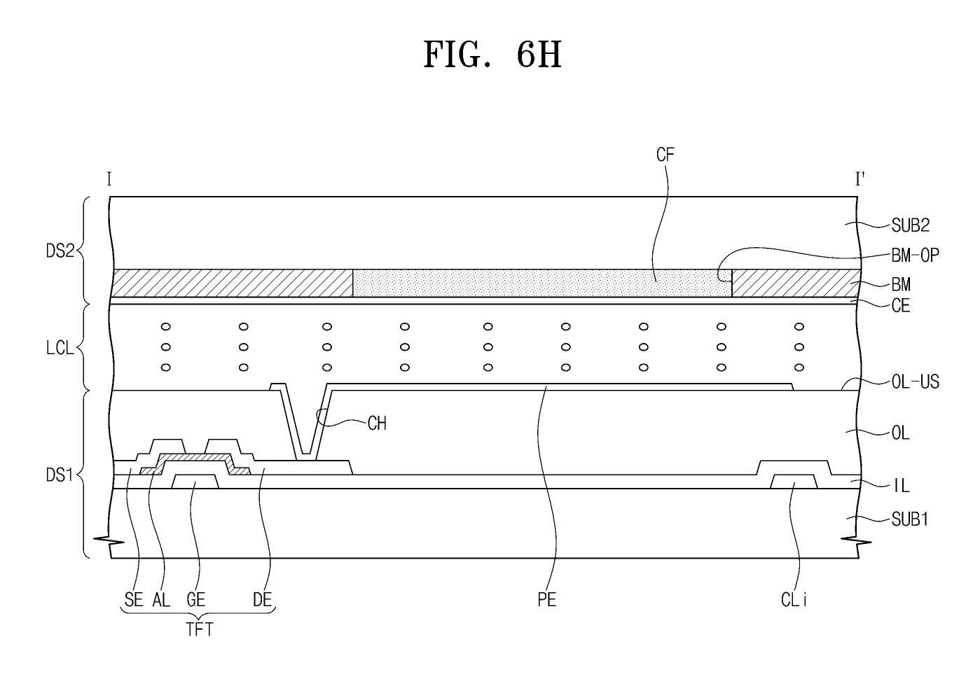

FIGS. 6A to 6H are cross-sectional views illustrating a method of manufacturing a display panel according to an embodiment of the invention. FIGS. 6A to 6H correspond to an exemplary embodiment illustrated in the cross-sectional view of FIG. 4. Hereinafter the same reference symbols designate the same elements as those illustrated in FIGS. 1 to 5.

A first substrate DS1 and a second substrate DS2 are formed. After forming the first substrate DS1, the second substrate DS2 may be formed. The forming order of the first substrate DS1 and the second substrate DS2 is not limited. The first substrate DS1 and the second substrate DS2 may be formed separately or simultaneously.

As shown in FIG. 6A, a thin film transistor TFT is formed on a first base substrate SUB1. On the first base substrate SUB1, a common line CLᵢ, a gate line GLᵢ (See FIG. 3), and a gate electrode GE connected to the gate line GLᵢ are formed. A conductive layer (not shown) is formed by a sputtering method, and then, a photolithography process and an etching process are performed.

On the first base substrate SUB1, an insulating layer IL covering the common line CLᵢ, the gate line GLᵢ, and the gate electrode GE is formed. The insulating layer IL includes silicon nitride or silicon oxide. The insulating layer IL may be formed by plasma enhanced chemical vapor deposition (“PECVD”) process.

A semiconductor layer AL is formed on a portion of the insulating layer IL corresponding the thin film transistor TFT. The semiconductor layer AL is formed by forming a silicon layer by the PECVD process and performing a photolithography process and an etching process for patterning the silicon layer.

A conductive pattern is patterned on the semiconductor layer AL to form a source electrode SE and a drain electrode DE. The conductive layer (not shown) may be formed by a deposition method or a sputtering method, however the method is not limited thereto. The photolithography process and the etching process are performed with respect to the conductive layer to form the source electrode SE and the drain electrode DE.

In this case, the planarization properties of the insulating layer IL, the semiconductor layer AL, or the electrodes SE and DE are low. The insulating layer IL, the semiconductor layer AL, or the electrodes SE and DE could not relieve the step of an interface thus formed. Therefore, the upper surface of the insulating layer IL, the semiconductor layer AL, and the electrodes SE and DE have a step.

As shown in FIG. 6B, an organic material layer OL-I is formed on the thin film transistor TFT and the common line CLᵢ. The organic material layer OL-I may be formed using a photosensitive resin composition. The photosensitive resin composition includes about 10 to about 50 wt % of a solute including about 100 parts by weight of an acryl-based copolymer, and about 5 to about 100 parts by weight of a 1,2-quinondiazide compound, and a remaining amount of a solvent.

The acryl-based copolymer is a copolymer of an unsaturated carbonic acid or an anhydride thereof, an epoxy group-containing unsaturated compound, and an olefin-based unsaturated compound. The solvent includes a glycol-based material having a high boiling point. In this embodiment, the glycol-based material having a high boiling point means a glycol-based material having a boiling point of about 190° C. to about 1,000° C. The solvent may include the glycol-based material having a high boiling point alone, or a mixture with other materials.

The organic material layer OL-I may be formed by various methods. For example, a spray method, a roll coater method, a rotation coating method, and the like, however the method is not limited thereto.

As shown in FIGS. 6C and 6D, the organic material layer OL-I coated on the first base substrate SUB1 is dried. Solvents in the organic material layer OL-I formed into a relatively thick layer on the first base substrate SUB 1 are removed through the drying process. The thickness of the organic material layer OL-I decreases through the removal of the solvents, and a planarization layer OL (Hereinafter will be referred to as a planarization layer) is formed. The drying process may be, for example, a vacuum drying process.

With the removal of the solvents included in the organic material layer OL-I, the viscosity of the organic material layer OL-I decreases, and drying proceeds slowly to form the planarization layer OL. Thus, the blur noise or the viscosity of the organic material layer OL-I is determined by the solvents included in the organic material layer OL-I.

The removing time of the solvent during the drying process influences the planarity of the planarization layer OL. To secure the time for forming a planar surface of the organic material layer OL-I on the first base substrate SUB1, the removing time of the solvents may be extended by gradually decreasing pressure. However, in this case, a processing time may be prolonged.

In exemplary embodiments, the organic material layer OL-I forming the planarization layer OL includes a photosensitive resin composition including a glycol-based solvent having a high boiling point. The glycol-based solvent having a high boiling point may delay the increasing viscosity phenomenon associated with drying the solvent in the vacuum drying process.

For example, in the case that a highly volatile solvent of a low boiling point is used as a main solvent, and a small amount of the glycol-based solvent having a high boiling point is added, the solvent having a low boiling point may be dried at the beginning of the vacuum drying process. The small amount of the glycol-based solvent having a high boiling point remaining later in the drying process, maintains a planarization treatment, and forms a final planarization layer OL. The organic material layer OL-I including the glycol-based solvent having a high boiling point is advantageous in that the drying time remains short thereby securing the productivity of the manufacturing process, while simultaneously controlling the planarity by forming the planarization layer OL having improved planarization properties.

As shown in FIG. 6D, the planarization layer OL formed by removing the solvent relieves the step formed by the thin film transistor TFT and the common line CLᵢ. The planarization layer OL is formed using a photosensitive resin composition including the glycol-based solvent having a high boiling point, and as a result, a top surface having an average leveling step of less than about 6,000 Å may be formed.

Even though not illustrated, the planarization layer OL may include at least one pattern. The solvent in the organic material layer OL-I may be removed through a pre-bake process. After removing the solvent, a mask is disposed on the first base substrate SUB1, a light is irradiated onto the surface of the substrate SUB1, and a developing process is performed to form a pattern on the surface.

A developing solution used in the developing process may be an aqueous alkaline solution. In particular, the aqueous alkaline solution may be an aqueous solution of inorganic alkaline salts including sodium hydroxide, potassium hydroxide, and sodium carbonate; primary amines including ethylamine, and n-propylamine; secondary amines including diethylamine, and n-propylamine; tertiary amines including trimethylamine, methyldiethylamine, dimethylethylamine, and triethylamine; alcohol amines such as dimethylethanolamine, methyldiethanolamine, and triethanolamine; or quaternary ammonium salts including tetramethylammonium hydroxide, and teteraethylammonium hydroxide may be used. In this case, the developing solution is used by dissolving an alkaline compound in an aqueous organic solvent such as methanol, and ethanol, and a surfactant. The concentration of the alkaline compound in the aqueous alkaline solution may be about 0.1 wt % to about 10 wt %.

After the developing process has been completed using the developing solution, a cleaning process using pure water is performed to remove unnecessary parts, and a drying process is performed to form a pattern. The pattern thus formed is exposed to a light such as ultraviolet light, and the pattern is heat treated by a heating apparatus such as an oven to obtain a final pattern.

As shown in FIG. 6E, a pixel electrode PE is formed on the planarization layer OL to form a first substrate DS1. A contact hole CH is formed in an area in which the planarization layer OL overlaps with the drain electrode DE, and an electrode layer is patterned on the planarization layer OL to form the pixel electrode PE. The pixel electrode PE is connected to the drain electrode DE through the contact hole CH. A passivation layer (not shown) covering the pixel electrode PE and an alignment layer (not shown) may be further formed on the pixel electrode PE.

As shown in FIG. 6F, the first substrate DS1 and the second substrate DS2 are combined. The second substrate DS2 is obtained by forming a black matrix BM on a second base substrate SUB2. The black matrix BM may be formed by coating an organic layer of a black color on the second base substrate SUB2 and patterning an opening part BM-OP. In an exemplary embodiment, the opening part BM-OP is filled with an organic layer having a color to form a color filter CF layer.

Then, a common electrode CE is formed on the black matrix BM and the color filter CF. A passivation layer (not shown) covering the common electrode CE or an alignment layer (not shown) may be further formed on the common electrode CE.

A seal member SL (See FIG. 2) is formed between the first substrate DS1 and the second substrate DS2, and the first substrate DS1 and the second substrate DS2 are combined. The seal member SL may be formed on the first substrate DS1 or on the second substrate DS2. The seal member SL may be formed by an insulating layer having adhesiveness at the boundary area of the first substrate DS1 or the second substrate DS2 and then patterning the insulating area, or by an inkjet printing method. The seal member SL forms and maintains a cell gap between the first substrate DS1 and the second substrate DS2.

As shown in FIG. 6G, liquid crystal LC is injected between the combined first substrate DS1 and the second substrate DS2. The liquid crystal LC spreads through the cell gap in one direction with a pixel as a reference and fills up the cell gap. The display panel includes a planarization layer OL formed by using a photosensitive resin composition including a glycol-based solvent having a high boiling point, and so a planarized top surface is provided on the passage of the injected liquid crystal LC.

The planarization layer OL decreases the step between the transparent area TA, and the shielding area SA, in which the thin film transistor TFT and a plurality of signal wires are disposed, to a height of less than about 6,000 Å. Thus, the liquid crystal LC may easily pass in the shielding area SA.

As shown in FIG. 6H, the liquid crystal LC (See FIG. 6G) is uniformly coated on the planarization layer to form a liquid crystal layer LCL. The liquid crystal layer LCL may maintain a uniform cell gap across the entire surface of a display panel due to the planarization layer OL. Since the alignment molecules of the liquid crystal layer LCL are uniformly aligned, a uniform electric field over the entire surface of the display panel may be formed, and the display quality may be improved.

The exemplary display panel described herein may include an planarization layer having a small thickness and high planarization properties. The exemplary planarization layer OL provides a planarization surface across which liquid crystals may distribute uniformly, without the need to perform a separate planarization process. The planarization layer OL provides a planar surface having good planarization properties in a structure including a large number of wires, for example, a ultra high definition (“UHD”) display panel having complicated distribution of the shielding area SA and a wide area.

The planarization layer OL formed using a photosensitive resin composition including the glycol-based solvent having a high boiling point may provide planarity and prevent the generation of coating stain to form a uniform pattern profile.

In addition, since the display panel is manufactured using a glycol-based solvent having a high boiling point, display properties such as uniform planarity, sensitivity, resolution, adhesiveness, transmittance, and contrast ratio may be improved. Particularly, since the glycol-based solvent having a high boiling point has good compatibility with the acryl-based copolymer and the 1,2-quinonediazide compound, the planarization properties may be good, and an ultra fine display device having a large area may be manufactured.

Hereinafter preferred embodiments will be described to assist the understanding of the invention. However, the embodiments are illustrated as example embodiments, and the scope of the invention is not limited to the following embodiments.

### Synthetic Example 1

Preparation of Acryl-Based Copolymer

A mixture of about 400 parts by weight of tetrahydrofuran, about 30 parts by weight of methacrylic acid, about 30 parts by weight of styrene, and about 40 parts by weight of glycidyl methacrylate was added into a flask equipped with a cooler and a stirrer. The mixture was sufficiently mixed in a mixing vessel at about 600 revolution per minute (rpm), and about 15 parts by weight of 2,2′-azobis(2,4-dimethyl valeronitrile) was added. The temperature of the mixture for polymerization was slowly increased to about 55° C. and this temperature was maintained for about 24 hours. Then the mixture was cooled to room temperature, and about 500 parts per million (ppm) of hydrobenzophenone as a polymerization inhibiting agent was added to obtain a polymer solution having a solids content of about 30 wt %. To remove unreacted monomers from the polymer solution, about 100 parts by weight of the polymerization solution was precipitated using about 1,000 parts by weight of n-hexane. After the precipitation, a poor solvent was removed through a filtering process using a mesh. After performing the filtering process, a vacuum drying process was performed at a temperature of less than about 30° C., and remaining unreacted monomers were removed to prepare an acryl-based copolymer. The weight average molecular weight (Mw) of the acryl-based copolymer was about 6,000 g/mol. In this case, the weight average molecular weight is a polystyrene converted average molecular weight measured by using a gel permeation chromatography (“GPC”).

### Synthetic Example 2

### Preparation of 1,2-Quinonediazide Compound

4,4′-[1-[4-[1-[4-hydroxyphenyl]-1-methylethyl]phenyl]ethylidene]bisphenol 1,2-naphthoquinonediazide-5-sulfonic acid ester was prepared by the condensation reaction of about 1 mol of 4,4′-[1-[4-[1-[4-hydroxyphenyl]-1-methylethyl]phenyl]ethylidene]bisphenol and about 2 mol of 1,2-naphthoquinonediazide-5-sulfonic acid [chloride].

### Example 1

### Preparation of Photosensitive Resin Composition

A photosensitive resin composition was prepared by dissolving about 100 parts by weight of the acryl-based copolymer prepared in Synthetic Example 1, about 30 parts by weight of the 4,4′-[1-[4-[1-[4-hydroxyphenyl]-1-methylethyl]phenyl]ethylidene]bisphenol 1,2-naphthoquinonediazide-5-sulfonic acid ester synthesized in Synthetic Example 2 in triethylene glycol dimethyl ether so that the solid content of the mixture was about 20 wt %, and filtering using a Millipore filter having a pore diameter of about 0.1 μm.

### Example 2

A photosensitive resin composition was prepared by performing the same procedure described in Example 1 except that diethylene glycol butyl methyl ether was used instead of triethylene glycol dimethyl ether.

### Example 3

A photosensitive resin composition was prepared by performing the same procedure described in Example 1 except that triethylene glycol butyl methyl ether was used instead of triethylene glycol dimethyl ether.

### Example 4

A photosensitive resin composition was prepared by performing the same procedure described in Example 1 except that diethylene glycol tert-butyl ether was used instead of triethylene glycol dimethyl ether.

### Example 5

A photosensitive resin composition was prepared by performing the same procedure described in Example 1 except that tetraethylene glycol dimethyl ether was used instead of triethylene glycol dimethyl ether.

### Example 6

A photosensitive resin composition was prepared by performing the same procedure described in Example 1 except that dipropylene glycol diethyl ether was used instead of triethylene glycol dimethyl ether.

### Example 7

A photosensitive resin composition was prepared by performing the same procedure described in Example 1 except that diethylene glycol ethyl hexyl ether was used instead of triethylene glycol dimethyl ether.

### Example 8

A photosensitive resin composition was prepared by performing the same procedure described in Example 1 except that about 10 parts by weight of dioctyl phthalate was additionally used.

### Example 9

A photosensitive resin composition was prepared by performing the same procedure described in Example 8 except that 2,2,4-trimethyl-1,3-pentanediol diisobutyrate was used instead of dioctyl phthalate.

### Example 10

A photosensitive resin composition was prepared by performing the same procedure described in Example 1 except that a mixture of diethylene glycol monomethyl ether and propylene glycol monomethyl ether acetate was used instead of triethylene glycol dimethyl ether. However, the mixing ratio of the mixture was changed as follows: a photosensitive resin composition of Example 10a was prepared by using 100 wt % of diethylene glycol monomethyl ether, a photosensitive resin composition Example 10b was prepared by using about 15 wt % of diethylene glycol monomethyl ether and about 85 wt % of propylene glycol monomethyl ether acetate, a photosensitive resin composition of Example 10c was prepared by using about 10 wt % of diethylene glycol monomethyl ether and about 90 wt % of propylene glycol monomethyl ether acetate, a photosensitive resin composition of Example 10d was prepared by using about 5 wt % of diethylene glycol monomethyl ether and about 95 wt % of propylene glycol monomethyl ether acetate, a photosensitive resin composition of Example 10e was prepared by using about 4 wt % of diethylene glycol monomethyl ether and about 96 wt % of propylene glycol monomethyl ether acetate, and a photosensitive resin composition of Example 10f was prepared by using about 3 wt % of diethylene glycol monomethyl ether and about 97 wt % of propylene glycol monomethyl ether acetate. Example 10 includes Examples 10a to 10f.

### Example 11

A photosensitive resin composition was prepared by performing the same procedure described in Example 1 except that a mixture of diethylene glycol monoethyl ether and propylene glycol monomethyl ether acetate was used instead of triethylene glycol dimethyl ether. However, the mixing ratio of the mixture was changed as follows: a photosensitive resin composition of Example 11a was prepared by using 100 wt % of diethylene glycol monoethyl ether, a photosensitive resin composition of Example 11b was prepared by using about 15 wt % of diethylene glycol monoethyl ether and about 85 wt % of propylene glycol monomethyl ether acetate, a photosensitive resin composition of Example 11c was prepared by using about 10 wt % of diethylene glycol monoethyl ether and about 90 wt % of propylene glycol monomethyl ether acetate, a photosensitive resin composition of Example 11d was prepared by using about 5 wt % of diethylene glycol monoethyl ether and about 95 wt % of propylene glycol monomethyl ether acetate, a photosensitive resin composition of Example 11e was prepared by using about 4 wt % of diethylene glycol monoethyl ether and about 96 wt % of propylene glycol monomethyl ether acetate, and a photosensitive resin composition of Example 11f was prepared by using about 3 wt % of diethylene glycol monoethyl ether and about 97 wt % of propylene glycol monomethyl ether acetate. Example 11 includes Examples 11a to 11f.

### Example 12

A photosensitive resin composition was prepared by performing the same procedure described in Example 1 except that a mixture of diethylene glycol butyl methyl ether and propylene glycol monomethyl ether acetate was used instead of triethylene glycol dimethyl ether. However, the mixing ratio of the mixture was changed as follows: a photosensitive resin composition of Example 12a was prepared by using 100 wt % of diethylene glycol butyl methyl ether, a photosensitive resin composition of Example 12b was prepared by using about 15 wt % of diethylene glycol butyl methyl ether and about 85 wt % of propylene glycol monomethyl ether acetate, a photosensitive resin composition of Example 12c was prepared by using about 10 wt % of diethylene glycol butyl methyl ether and about 90 wt % of propylene glycol monomethyl ether acetate, a photosensitive resin composition of Example 12d was prepared by using about 5 wt % of diethylene glycol butyl methyl ether and about 95 wt % of propylene glycol monomethyl ether acetate, a photosensitive resin composition of Example 12e was prepared by using about 4 wt % of diethylene glycol butyl methyl ether and about 96 wt % of propylene glycol monomethyl ether acetate, and a photosensitive resin composition of Example 12f was prepared by using about 3 wt % of diethylene glycol butyl methyl ether and about 97 wt % of propylene glycol monomethyl ether acetate. Example 12 includes Examples 12a to 12f.

### Example 13

A photosensitive resin composition was prepared by performing the same procedure described in Example 1 except that a mixture of triethylene glycol butyl methyl ether and propylene glycol monomethyl ether acetate was used instead of triethylene glycol dimethyl ether. However, the mixing ratio of the mixture was changed as follows: a photosensitive resin composition of Example 13a was prepared by using 100 wt % of triethylene glycol butyl methyl ether, a photosensitive resin composition of Example 13b was prepared by using about 15 wt % of triethylene glycol butyl methyl ether and about 85 wt % of propylene glycol monomethyl ether acetate, a photosensitive resin composition of Example 13c was prepared by using about 10 wt % of triethylene glycol butyl methyl ether and about 90 wt % of propylene glycol monomethyl ether acetate, a photosensitive resin composition of Example 13d was prepared by using about 5 wt % of triethylene glycol butyl methyl ether and about 95 wt % of propylene glycol monomethyl ether acetate, a photosensitive resin composition of Example 13e was prepared by using about 4 wt % of triethylene glycol butyl methyl ether and about 96 wt % of propylene glycol monomethyl ether acetate, and a photosensitive resin composition of Example 13f was prepared by using about 3 wt % of triethylene glycol butyl methyl ether and about 97 wt % of propylene glycol monomethyl ether acetate. Example 13 includes Examples 13a to 13f.

### Comparative Example 1

A photosensitive resin composition was prepared by performing the same procedure described in Example 1 except that propylene glycol methyl ether acetate was used instead of triethylene glycol dimethyl ether.

### Comparative Example 2

A photosensitive resin composition was prepared by performing the same procedure described in Example 1 except that propylene glycol methyl ether propionate was used instead of triethylene glycol dimethyl ether.

### Comparative Example 3

A photosensitive resin composition was prepared by performing the same procedure described in Example 1 except that ethylene glycol methyl ether was used instead of triethylene glycol dimethyl ether.

### Comparative Example 4

A photosensitive resin composition was prepared by performing the same procedure described in Example 1 except that a mixture of diethylene glycol methyl ethyl ether and propylene glycol monomethyl ether acetate was used instead of triethylene glycol dimethyl ether. However, the mixing ratio of the mixture was changed as follows: a photosensitive resin composition of Comparative Example 4a was prepared by using 100 wt % of diethylene glycol methyl ethyl ether, a photosensitive resin composition of Comparative Example 4b was prepared by using about 15 wt % of diethylene glycol methyl ethyl ether and about 85 wt % of propylene glycol monomethyl ether acetate, a photosensitive resin composition of Comparative Example 4c was prepared by using about 10 wt % of diethylene glycol methyl ethyl ether and about 90 wt % of propylene glycol monomethyl ether acetate, a photosensitive resin composition of Comparative Example 4d was prepared by using about 5 wt % of diethylene glycol methyl ethyl ether and about 95 wt % of propylene glycol monomethyl ether acetate, a photosensitive resin composition of Comparative Example 4e was prepared by using about 4 wt % of diethylene glycol methyl ethyl ether and about 96 wt % of propylene glycol monomethyl ether acetate, and a photosensitive resin composition of Comparative Example 4f was prepared by using about 3 wt % of diethylene glycol methyl ethyl ether and about 97 wt % of propylene glycol monomethyl ether acetate. Comparative Example 4 includes Comparative Examples 4a to 4f.

### Comparative Example 5

A photosensitive resin composition was prepared by performing the same procedure described in Example 1 except that a mixture of diethylene glycol diethyl ether and propylene glycol monomethyl ether acetate was used instead of triethylene glycol dimethyl ether. However, the mixing ratio of the mixture was changed as follows: a photosensitive resin composition of Comparative Example 5a was prepared by using 100 wt % of diethylene glycol diethyl ether, a photosensitive resin composition of Comparative Example 5b was prepared by using about 15 wt % of diethylene glycol diethyl ether and about 85 wt % of propylene glycol monomethyl ether acetate, a photosensitive resin composition of Comparative Example 5c was prepared by using about 10 wt % of diethylene glycol diethyl ether and about 90 wt % of propylene glycol monomethyl ether acetate, a photosensitive resin composition of Comparative Example 5d was prepared by using about 5 wt % of diethylene glycol diethyl ether and about 95 wt % of propylene glycol monomethyl ether acetate, a photosensitive resin composition of Comparative Example 5e was prepared by using about 4 wt % of diethylene glycol diethyl ether and about 96 wt % of propylene glycol monomethyl ether acetate, and a photosensitive resin composition of Comparative Example 5f was prepared by using about 3 wt % of diethylene glycol diethyl ether and about 97 wt % of propylene glycol monomethyl ether acetate. Comparative Example 5 includes Comparative Examples 5a to 5f.

### Comparative Example 6

A photosensitive resin composition was prepared by performing the same procedure described in Example 1 except that a mixture of dipropylene glycol dimethyl ether and propylene glycol monomethyl ether acetate was used instead of triethylene glycol dimethyl ether. However, the mixing ratio of the mixture was changed as follows: a photosensitive resin composition of Comparative Example 6a was prepared by using 100 wt % of dipropylene glycol dimethyl ether, a photosensitive resin composition of Comparative Example 6b was prepared by using about 15 wt % of dipropylene glycol dimethyl ether and about 85 wt % of propylene glycol monomethyl ether acetate, a photosensitive resin composition of Comparative Example 6c was prepared by using about 10 wt % of dipropylene glycol dimethyl ether and about 90 wt % of propylene glycol monomethyl ether acetate, a photosensitive resin composition of Comparative Example 6d was prepared by using about 5 wt % of dipropylene glycol dimethyl ether and about 95 wt % of propylene glycol monomethyl ether acetate, a photosensitive resin composition of Comparative Example 6e was prepared by using about 4 wt % of dipropylene glycol dimethyl ether and about 96 wt % of propylene glycol monomethyl ether acetate, and a photosensitive resin composition of Comparative Example 6f was prepared by using about 3 wt % of dipropylene glycol dimethyl ether and about 97 wt % of propylene glycol monomethyl ether acetate. Comparative Example 6 includes Comparative Examples 6a to 6f.

The physical properties of the photosensitive resin compositions prepared in Examples 1 to 9 and Comparative Examples 1 to 3 were measured and the results are illustrated in the following Table 3.

A) Uniformity—Positive type photosensitive resin compositions prepared in Examples 1 to 9 and Comparative Examples 1 to 3 were coated on a glass substrate having a size of about 370 centimeters (cm)×470 cm, on which silicon nitride (SiNₓ) was deposited, by using a slit coater. Then, a vacuum conductive drying (“VCD”) was performed to about 0.5 torr, and pre-baking was performed at about 100° C. on a hot plate for about 2 minutes to form a coating layer having a thickness of about 4.0 μm. To evaluate the uniformity, thickness difference at each area of the coating layer was measured. In Table 3, ∘ indicates when the uniformity was less than about 3%, Δ indicates when the uniformity was about 3% to about 5%, and x indicates when the uniformity was at least about 5%.

B) Sensitivity (millijoules per centimeter squared: mJ/cm²)—With respect to the layer formed in the above A), an ultraviolet light having the intensity of about 25 milliwatts per centimeter squared (mW/cm²) in a broadband was irradiated for about 1 to about 10 seconds with the interval of about 1 second by using a pattern mask having a contact hole critical dimension (“CD”) of about 12 μm×14 μm, and having about 75% of the half tone transmittance of a pad part. Then, a developing process was performed using an aqueous solution of about 2.38 wt % tetramethyl ammonium hydroxide at about 23° C. for about 70 seconds, and a cleaning process was performed using pure water for about 60 seconds. For final curing, a heating treatment was performed in an oven at about 230° C. for about 30 minutes. The sensitivity was measured by using a scanning electron microscope (“SEM”) with the dosage of forming the contact hole CD of about 9.5 μm×12.5 μm as a reference.

C) Limiting resolution—Limiting resolution was measured as a minimum size with the contact hole of the pattern layer formed in the above B) for measuring the sensitivity as a reference. However, the limiting resolution was designated in the case that critical dimension bias was the same.

D) Contact hole scum—Scum was examined with the contact hole of the pattern layer formed when measuring the sensitivity in A) as a reference. In Table 3, ∘ indicates when the scum was not found, and x indicates when the scum was found.

E) Adhesiveness—In Table 3, ∘ indicates when the minimum scum of the pattern layer of the pad part formed for measuring the sensitivity in B) was less than about 0.5 μm, Δ indicates when the scum was about 0.5 μm to about 1.5 μm, and x indicates when the scum was at least about 1.5 μm.

F) Transmittance—The evaluation of the transmittance was performed with respect to the pattern layer formed for measuring the sensitivity in A). The transmittance of the pattern layer was measured using a spectrophotometer. The transmittance thus measured and the transmittance of about 400-800 nm were added as the transmittance of the examples. In Table 3, ∘ indicates when the transmittance was at least about 98%, Δ indicates when the transmittance was about 95% to about 98%, and x indicates when the transmittance was less than about 95%. The measuring of the transmittance was performed based on a bare glass.

G) Contrast ratio—The substrate used for the evaluation of the transmittance in F) was installed between polarizing plates of a normally white mode by using a contrast tester (Model: CT-1). In this experiment, white luminance and black luminance were measured and the ratio of the white luminance with respect to the black luminance (white luminance/black luminance) was measured as the contrast ratio. In Table 3, ∘ indicates when the contrast ratio was at least about 22,000, Δ indicates when the contrast ratio was about 20,000 to about 22,000, and x indicates when the contrast ratio was less than about 20,000.

H) Planarity—On a thin film transistor (“TFT”) substrate having a bottom step of about 1.0 μm to about 1.5 μm, a coating process, a developing process and a curing process were performed with the conditions in A) and B). The planarity was evaluated through the step difference of the overlapping part of the channel of a thin film transistor substrate and the overlapping part of a pixel. In Table 3, ∘ indicates when the step difference of a shielding area and a transparent area was less than about 5%, Δ indicates when the step difference was about 5% to about 10%, and x indicates when the step difference was at least about 10%.

TABLE 3

| | | | Limiting | Contact | | | | |
|---|---|---|---|---|---|---|---|---|
| | | Sensitivity | resolution | hole | | | Contrast | |
| | Uniformity | (mJ/cm²) | (μm) | scum | Adhesiveness | Transmittance | ratio | Planarity |
| Example 1 | ∘ | 140 | 5 | ∘ | ∘ | ∘ | ∘ | ∘ |
| Example 2 | ∘ | 139 | 5 | ∘ | ∘ | ∘ | ∘ | ∘ |
| Example 3 | ∘ | 138 | 5 | ∘ | ∘ | ∘ | ∘ | ∘ |
| Example 4 | ∘ | 140 | 5 | ∘ | ∘ | ∘ | ∘ | ∘ |
| Example 5 | ∘ | 140 | 5 | ∘ | ∘ | ∘ | ∘ | ∘ |
| Example 6 | ∘ | 137 | 5 | ∘ | ∘ | ∘ | ∘ | ∘ |
| Example 7 | ∘ | 135 | 5 | ∘ | ∘ | ∘ | ∘ | ∘ |
| Example 8 | ∘ | 140 | 5 | ∘ | ∘ | ∘ | ∘ | ∘ |
| Example 9 | ∘ | 138 | 5 | ∘ | ∘ | ∘ | ∘ | ∘ |
| Comparative | ∘ | 138 | 5 | ∘ | ∘ | ∘ | ∘ | x |
| Example 1 | | | | | | | | |
| Comparative | ∘ | 141 | 5 | ∘ | ∘ | ∘ | ∘ | x |
| Example 2 | | | | | | | | |
| Comparative | ∘ | 140 | 5 | ∘ | ∘ | ∘ | ∘ | x |
| Example 3 | | | | | | | | |

In addition, the planarity of the photosensitive resin compositions of Examples 10 to 13 and Comparative Examples 4 to 6 was measured and the results are illustrated in the following Table 4. On a TFT substrate having a bottom step of about 1.0 μm to about 1.5 μm, a coating process, a developing process and a curing process were performed with the conditions in A) and B). The planarity was evaluated through the step difference of the overlapping part of the channel of a thin film transistor substrate and the overlapping part of a pixel. In Table 4, ∘ indicates when the step difference of a shielding area and a transparent area was less than about 5%, Δ indicates when the step difference was about 5% to about 10%, and x indicates when the step difference was at least about 10%.

TABLE 4

| | Comparative | Comparative | Comparative | Example | Example | Example | Example |
|---|---|---|---|---|---|---|---|
| | Example 4a | Example 5a | Example 6a | 10a | 11a | 12a | 13a |
| Boiling | 176° C. | 189° C. | 171° C. | 194° C. | 201° C. | 212° C. | 261° C. |
| point (° C.) | | | | | | | |
| Planarity | 12.5% | 10.5% | 13.0% | 3.8% | 3.5% | 2.0% | 1.5% |
| | x | x | x | ∘ | ∘ | ∘ | ∘ |
| | Comparative | Comparative | Comparative | Example | Example | Example | Example |
| | Example 4b | Example 5b | Example 6b | 10b | 11b | 12b | 13b |
| Planarity | 13.5% | 11.4% | 15.4% | 3.7% | 3.4% | 2.4% | 2.0% |
| | x | x | x | ∘ | ∘ | ∘ | ∘ |
| | Comparative | Comparative | Comparative | Example | Example | Example | Example |
| | Example 4c | Example 5c | Example 6c | 10c | 11c | 12c | 13c |
| Planarity | 14.0% | 12.0% | 15.8% | 4.2% | 4.0% | 3.1% | 2.5% |
| | x | x | x | ∘ | ∘ | ∘ | ∘ |
| | Comparative | Comparative | Comparative | Example | Example | Example | Example |
| | Example 4d | Example 5d | Example 6d | 10d | 11d | 12d | 13d |
| Planarity | 14.4% | 12.5% | 16.0% | 4.7% | 4.5% | 3.6% | 3.0% |
| | x | x | x | ∘ | ∘ | ∘ | ∘ |
| | Comparative | Comparative | Comparative | Example | Example | Example | Example |
| | Example 4e | Example 5e | Example 6e | 10e | 11e | 12e | 13e |
| Planarity | 14.8% | 13.6% | 16.2% | 9.7% | 8.5% | 6.5% | 5.7% |
| | x | x | x | Δ | Δ | Δ | Δ |
| | Comparative | Comparative | Comparative | Example | Example | Example | Example |
| | Example 4f | Example 5f | Example 6f | 10f | 11f | 12f | 13f |
| Planarity | 15.4% | 14.5% | 16.5% | 12.7% | 11.5% | 10.5% | 10.2% |
| | x | x | x | x | x | x | x |

The above-disclosed subject matter is to be considered illustrative and not restrictive. The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the invention. Accordingly, all such modifications are intended to be included within the scope of the invention as defined in the claims. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

Thus, to the maximum extent allowed by law, the scope of the invention is to be determined by the broadest permissible interpretation of the following claims and their equivalents, and shall not be restricted or limited by the foregoing detailed description.

What is claimed is:

1. A photosensitive resin composition, comprising:
about 10 wt % to about 50 wt % of a solute comprising about 100 parts by weight of an acryl-based copolymer and about 5 to about 100 parts by weight of a 1,2-quinonediazide compound; and
a solvent comprising a glycol-based material having a boiling point of greater than about 190° C.,
wherein the acryl-based copolymer is a copolymer of an unsaturated carbonic acid or an anhydride thereof, an epoxy group-containing unsaturated compound, and an olefin-based unsaturated compound.

2. The photosensitive resin composition of claim 1, wherein the acryl-based copolymer comprises:
about 5 to about 45 parts by weight of the unsaturated carbonic acid or the anhydride thereof;
about 10 to about 70 parts by weight of the epoxy group-containing unsaturated compound; and
about 10 to about 70 parts by weight of the olefin-based unsaturated compound.

3. The photosensitive resin composition of claim 1, wherein the solvent comprises at least one of diethylene glycol butyl methyl ether, diethylene glycol butyl ethyl ether, triethylene glycol dimethyl ether, triethylene glycol butyl methyl ether, diethylene glycol tert-butyl ether, tetraethylene glycol dimethyl ether, dipropylene glycol diethyl ether, diethylene glycol ethyl hexyl ether, diethylene glycol methyl hexyl ether, dipropylene glycol butyl methyl ether, dipropylene glycol ethyl hexyl ether, and dipropylene glycol methyl hexyl ether.

4. The photosensitive resin composition of claim 3, wherein the solvent further comprises at least one of an alcohol, an ethylene glycol alkyl ether acetate, an ethylene glycol alkyl ether propionate, an ethylene glycol monoalkyl ether, a propylene glycol alkyl ether propionates a propylene glycol monoalkyl ether, dipropylene glycol dimethyl ether, diethylene glycol methyl ethyl ether, methyl beta-methoxy propionate, and ethyl beta-ethoxy propionate.

5. The photosensitive resin composition of claim 4, wherein an amount of the glycol-based material is at least about 5 wt % based on 100 wt % of the photosensitive resin composition.

6. The photosensitive resin composition of claim 1, further comprising about 0.0001 to about 10 parts by weight of a plasticizer based on about 100 parts by weight of the acryl-based copolymer.

7. The photosensitive resin composition of claim 6, wherein the plasticizer comprises at least one of dioctyl phthalate, diisononyl phthalate, dioctyl adipate, tricresyl phosphate, 2,2,4-trimethyl-1,3-pentanediol monoisobutyrate, and 2,2,4-trimethyl-1,3-pentanediol diisobutyrate.

8. A display device, comprising:
a first base substrate comprising a transparent area, a shielding area adjacent to the transparent area, and a plurality of signal wires in the shielding area;
a planarization layer overlapping the transparent area and the shielding area and covering the plurality of signal wires, wherein the planarization layer comprises a cured product of a photosensitive resin composition; and
a pixel electrode on the planarization layer and overlapping the transparent area,
wherein the photosensitive resin composition comprises:
about 10 wt % to about 50 wt % of a solute comprising about 100 parts by weight of an acryl-based copolymer and about 5 to about 100 parts by weight of a 1,2-quinonediazide compound; and
a solvent comprising a glycol-based material having a boiling point of greater than about 190° C.,
wherein the acryl-based copolymer is a copolymer of an unsaturated carbonic acid or an anhydride thereof, an epoxy group-containing unsaturated compound, and an olefin-based unsaturated compound.

9. The display device of claim 8, wherein the photosensitive resin composition further comprises about 0.0001 to about 10 parts by weight of a plasticizer based on about 100 parts by weight of the acryl-based copolymer.

10. The display device of claim 8, further comprising a thin film transistor disposed in the shielding area, wherein the thin film transistor is connected to a signal wire from among the plurality of signal wires and to the pixel electrode, and
wherein the planarization layer covers the thin film transistor.

11. The display device of claim 10, wherein the planarization layer comprises at least one step on a top surface, and
wherein a height of the step is less than about 5,000 Å as measured by a difference between a distance from a top surface of the first base substrate to a top surface of the step and a distance from the top surface of the first base substrate to the planarization layer.

12. The display device of claim 11, wherein the planarization layer comprises at least one color.

13. The display device of claim 11, further comprising:
a second base substrate disposed above the first base substrate and facing the first base substrate;
at least one color pattern on the second base substrate and overlapping the transparent area of the first base substrate; and
a black matrix adjacent to the color pattern and overlapping the shielding area of the first base substrate.

14. The display device of claim 13, further comprising a liquid crystal layer encapsulated between the first base substrate and the second base substrate, and
wherein the liquid crystal layer covers the step of the planarization layer.

15. A method of manufacturing a display device, comprising
forming a first display substrate; and
forming a second display substrate on the first display substrate,
wherein the forming of the first display substrate comprises:
forming a first base substrate comprising a plurality of signal wires, and a thin film transistor connected to a signal wire among the plurality of signal wires;
coating an organic layer comprising a photosensitive resin composition on the first base substrate to cover the plurality of signal wires and the thin film transistor;
forming a planarization layer by curing the photosensitive resin composition; and
forming a pixel electrode electrically connected to the thin film transistor, on the planarization layer,
wherein the photosensitive resin composition comprises:
about 10 wt % to about 50 wt % of a solute comprising about 100 parts by weight of an acryl-based copolymer and about 5 to about 100 parts by weight of a 1,2-quinonediazide compound; and
a solvent comprising a glycol-based material having a boiling point of higher than about 190° C.,
wherein the acryl-based copolymer is with a copolymer of an unsaturated carbonic acid or an anhydride thereof, an epoxy group-containing unsaturated compound, and an olefin-based unsaturated compound.

16. The method of manufacturing a display device of claim 15, wherein the glycol-based material comprises at least one of diethylene glycol butyl methyl ether, diethylene glycol butyl ethyl ether, triethylene glycol dimethyl ether, triethylene glycol butyl methyl ether, diethylene glycol tert-butyl ether, tetraethylene glycol dimethyl ether, dipropylene glycol diethyl ether, diethylene glycol ethyl hexyl ether, diethylene glycol methyl hexyl ether, dipropylene glycol butyl methyl ether, dipropylene glycol ethyl hexyl ether, and dipropylene glycol methyl hexyl ether.

17. The method of manufacturing a display device of claim 16, wherein an amount of the glycol-based material is at least about 15 wt % based on the photosensitive resin composition.

18. The method of manufacturing a display device of claim 17, wherein the forming of the planarization layer comprises removing the solvent and curing the photosensitive resin composition.

19. The method of manufacturing a display device of claim 15, wherein the forming of the second display substrate comprises:
forming a second base substrate;
forming a black matrix on the second base substrate, and forming an opening part in the black matrix overlapping the pixel electrode; and
forming a common electrode on the black matrix.

20. The method of manufacturing a display device of claim 15, further comprising:
combining the first display substrate and the second display substrate; and
injecting liquid crystal between the first display substrate and the second display substrate.
